(19) United States
(12) Patent Application Publication
(10) Pub. No.: US 2026/0231647 A1
(43) Pub. Date: Aug. 6, 2026

(54) DISPLAY PANEL AND PREPARATION METHOD THEREFOR AND DISPLAY DEVICE

(71) Applicant: WUHAN TIANMA MICROELECTRONICS CO., LTD., Wuhan (CN)

(72) Inventors: Wei CHENG, Wuhan (CN); Dan HUANG, Wuhan (CN); Xiaojin ZHOU, Wuhan (CN)

(73) Assignee: WUHAN TIANMA MICROELECTRONICS CO., LTD., Wuhan (CN)

(21) Appl. No.: 19/636,160

(22) Filed: Apr. 1, 2026

(30) Foreign Application Priority Data
Nov. 6, 2025 (CN) 202511622097.4

(51) Int. Cl. H10K 59/65; G06V 40/13; H10K 59/121; H10K 59/124; H10K 59/131; H10K 102/00

(52) U.S. Cl. CPC H10K 59/65; G06V 40/1318; H10K 59/121; H10K 59/124; H10K 59/131; H10K 2102/351

(57) ABSTRACT

Provided are a display panel and a preparation method therefor and a display device. The display panel includes a base substrate, a first planarization layer, a first metal layer, a photosensitive element, an etching stop layer, and a light-emitting element. The photosensitive element includes a first electrode and a semiconductor layer that are electrically connected to each other, the first electrode is located in the first metal layer, and the semiconductor layer is located on one side of the etching stop layer facing away from the first metal layer. In the display region, the etching stop layer includes at least one first opening. Along a direction perpendicular to the plane where the base substrate is located, a first opening does not overlap with the first metal layer.

### CROSS-REFERENCE TO RELATED APPLICATION

This application claims priority to Chinese Patent Application No. 202511622097.4 filed Nov. 6, 2025, the disclosure of which is incorporated herein by reference in its entirety.

### TECHNICAL FIELD

The present disclosure relates to the field of display technology and, in particular, to a display panel and a preparation method therefor and a display device.

### BACKGROUND

As the demands of smart terminal devices for thinness, lightness, and high integration continuously increase, conventional external optical sensors (such as ambient light sensors, color temperature sensors, and under-screen fingerprint modules) can no longer meet the development trend of product design.

To address the preceding problem, optical sensors may be embedded into a display panel, which effectively reduces the overall module thickness and is conducive to improving the recognition precision and response consistency of the optical sensors.

However, in the process where the optical sensors are embedded into the display panel, problems such as film damage and reduced reliability may arise.

### SUMMARY

The present disclosure provides a display panel and a preparation method therefor and a display device to improve the reliability of the display panel and the display device.

According to one aspect of the present disclosure, a display panel is provided. The display panel includes a base substrate, a first planarization layer, a first metal layer, a photosensitive element, an etching stop layer, and a light-emitting element.

The first planarization layer is located on one side of the base substrate.

The first metal layer is located on one side of the first planarization layer facing away from the base substrate.

The photosensitive element is located in a display region of the display panel.

The etching stop layer is located on one side of the first metal layer facing away from the base substrate.

The light-emitting element is located on one side of the photosensitive element facing away from the base substrate.

The photosensitive element includes a first electrode and a semiconductor layer that are electrically connected to each other, the first electrode is located in the first metal layer, and the semiconductor layer is located on one side of the etching stop layer facing away from the first metal layer.

In the display region, the etching stop layer includes at least one first opening and at least one second opening.

Along a direction perpendicular to the plane where the base substrate is located, a first opening does not overlap with the first metal layer, an overlapping region exists among a second opening, the first electrode, and the semiconductor layer, and the first electrode and the semiconductor layer are connected to each other through the second opening.

According to another aspect of the present disclosure, a display device is provided. The display device includes the display panel described in the first aspect.

According to one aspect of the present disclosure, a preparation method for a display panel is provided. The preparation method for a display panel includes the steps described below.

A first planarization layer is formed on one side of a base substrate.

A first metal layer is formed on one side of the first planarization layer facing away from the base substrate, where the first metal layer includes a first electrode.

An etching stop layer is formed on one side of the first metal layer facing away from the base substrate.

The etching stop layer is etched so that at least one first opening and at least one second opening are formed in the etching stop layer, where the at least one first opening and the at least one second opening are located in a display region, and along a direction perpendicular to the plane where the base substrate is located, a first opening does not overlap with the first metal layer.

A semiconductor layer electrically connected to the first electrode is formed on one side of the etching stop layer facing away from the base substrate, where along the direction perpendicular to the plane where the base substrate is located, an overlapping region exists among a second opening, the first electrode, and the semiconductor layer, and the first electrode and the semiconductor layer are connected to each other through the second opening to form a photosensitive element located in the display region.

A light-emitting element is formed on one side of the photosensitive element facing away from the base substrate.

According to the display panel and the preparation method therefor and the display device in embodiments of the present disclosure, photosensitive elements are disposed in the display panel, thereby reducing the overall module thickness, and the first planarization layer is disposed under the photosensitive elements for planarization to ensure the consistent performance of each photosensitive element. Furthermore, the etching stop layer is added between the first metal layer and the semiconductor layer so that when the patterned semiconductor layer is formed through etching, the first metal layer and the first planarization layer are protected, and over-etching damage to the first metal layer and the first planarization layer is avoided. In addition, the first opening that does not overlap with the first metal layer is provided in the etching stop layer, serving as a gas release channel. During a process procedure (a high-temperature site) involving a high temperature in a fabrication process, a gas generated by the first planarization layer can be released outward through the first opening, thereby preventing the etching stop layer from peeling off from the first planarization layer and improving the reliability of the display panel.

It is to be understood that the content described in this section is neither intended to identify key or critical features of the embodiments of the present disclosure nor intended to limit the scope of the present disclosure. Other features of the present disclosure become easily understood through the description provided below.

### BRIEF DESCRIPTION OF DRAWINGS

To illustrate technical solutions in embodiments of the present disclosure more clearly, drawings used in the description of the embodiments are briefly described below. Apparently, the drawings described below illustrate some embodiments of the present disclosure, and those of ordinary skill in the art may obtain other drawings based on the drawings described below on the premise that no creative work is done.

FIG. 1 is a structural diagram of a display panel according to an embodiment of the present disclosure.

FIG. 2 is a sectional view taken along A-A′ of FIG. 1.

FIG. 3 is a partial structural diagram of a first metal layer and an etching stop layer in a display region according to an embodiment of the present disclosure.

FIG. 4 is a sectional view of a semiconductor layer according to an embodiment of the present disclosure.

FIG. 5 is a structural diagram of a fingerprint recognition module according to an embodiment of the present disclosure.

FIG. 6 is a sectional view of part of a display panel in a non-display region according to an embodiment of the present disclosure.

FIG. 7 is a partial structural diagram of an etching stop layer in a non-display region according to an embodiment of the present disclosure.

FIG. 8 is another partial structural diagram of an etching stop layer in a non-display region according to an embodiment of the present disclosure.

FIG. 9 is a sectional view of part of a display panel in a display region according to an embodiment of the present disclosure.

FIG. 10 is a structural diagram of a display device according to an embodiment of the present disclosure.

FIG. 11 is a flowchart of a preparation method for a display panel according to an embodiment of the present disclosure.

FIGS. 12 to 21 are structural diagrams illustrating a manufacturing method for a display panel according to an embodiment of the present disclosure.

### DETAILED DESCRIPTION

To make the technical solutions of the present disclosure better understood by those skilled in the art, the technical solutions in the embodiments of the present disclosure are described below clearly and completely in conjunction with the drawings in the embodiments of the present disclosure. Apparently, the embodiments described below are part, not all, of embodiments of the present disclosure. Based on the embodiments of the present disclosure, all other embodiments obtained by those of ordinary skill in the art are within the scope of the present disclosure on the premise that no creative work is done.

It is to be noted that terms such as “first” and “second” in the description, claims, and drawings of the present disclosure are used for distinguishing between similar objects and are not necessarily used for describing a particular order or sequence. It is to be understood that data used in this manner are interchangeable where appropriate so that the embodiments of the present disclosure described herein can be implemented in an order not illustrated or described herein. In addition, the terms “including”, “having”, and any variations thereof are intended to encompass a non-exclusive inclusion. For example, a process, method, system, product, or apparatus that includes a series of steps or units may include not only the expressly listed steps or units but also other steps or units that are not expressly listed or are inherent to such a process, method, product, or apparatus.

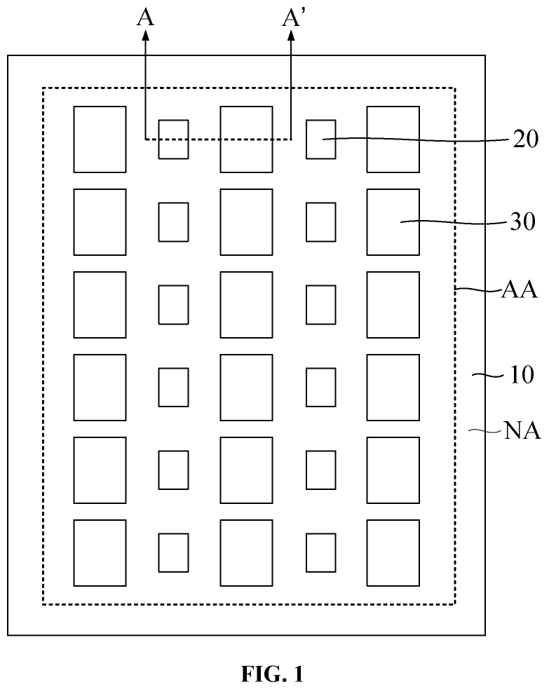

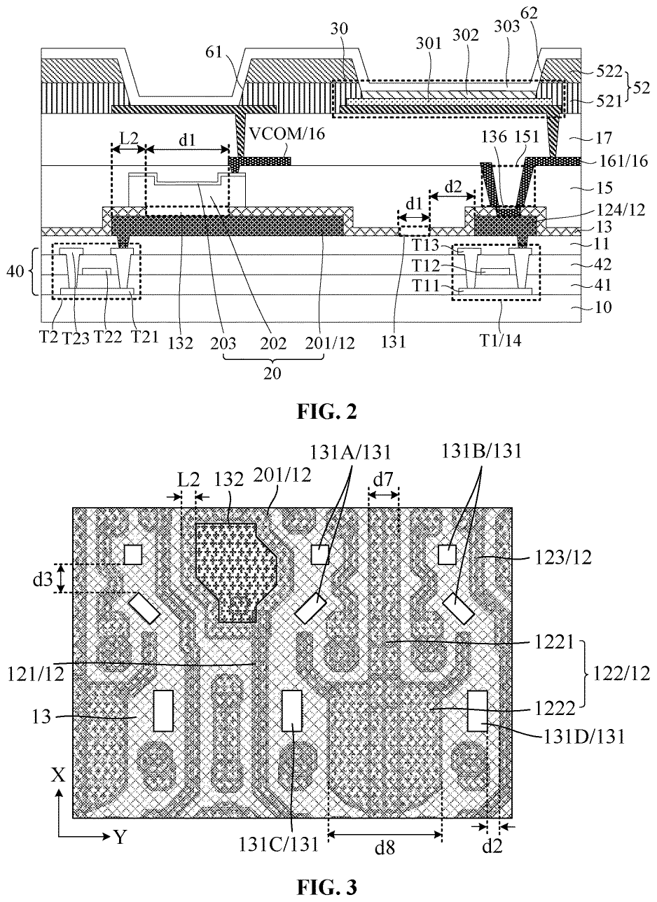

FIG. 1 is a structural diagram of a display panel according to an embodiment of the present disclosure, FIG. 2 is a sectional view taken along A-A′ of FIG. 1, and FIG. 3 is a partial structural diagram of a first metal layer and an etching stop layer in a display region according to an embodiment of the present disclosure. As shown in FIGS. 1 to 3, the display panel provided in the embodiment of the present disclosure includes a base substrate 10, a first planarization layer 11, a first metal layer 12, a photosensitive element 20, an etching stop layer 13, and a light-emitting element 30.

The first planarization layer 11 is located on one side of the base substrate 10.

The first metal layer 12 is located on one side of the first planarization layer 11 facing away from the base substrate 10.

The photosensitive element 20 is located in a display region AA of the display panel.

The etching stop layer 13 is located on one side of the first metal layer 12 facing away from the base substrate 10.

The light-emitting element 30 is located on one side of the photosensitive element 20 facing away from the base substrate 10.

The photosensitive element 20 includes a first electrode 201 and a semiconductor layer 202 that are electrically connected to each other. The first electrode 201 is located in the first metal layer 12. The semiconductor layer 202 is located on one side of the etching stop layer 13 facing away from the first metal layer 12.

In the display region AA, the etching stop layer 13 includes at least one first opening 131 and at least one second opening 132.

Along a direction perpendicular to the plane where the base substrate 10 is located, a first opening 131 does not overlap with the first metal layer 12, and an overlapping region exists among a second opening 132, the first electrode 201, and the semiconductor layer 202. The first electrode 201 and the semiconductor layer 202 are connected to each other through the second opening 132.

Specifically, as shown in FIGS. 1 and 2, the base substrate 10 is used for bearing various components in the display panel. The base substrate 10 may be a glass substrate so that the base substrate 10 has relatively high hardness and scratch resistance and can withstand relatively high mechanical stress during fabrication and use, reducing the risk of damage. In addition, the glass substrate can also provide relatively high surface flatness and smoothness, helping to ensure the uniformity of subsequently deposited films (such as an array layer) and reducing film defects and non-uniformity. In other embodiments, the base substrate 10 may be a flexible base made of other materials such as polyimide (PI). The material of the base substrate 10 is not specifically limited in the embodiment of the present disclosure.

Furthermore, multiple pixel circuits 14 arranged in an array and multiple light-emitting elements 30 arranged in an array are disposed in the display region AA of the display panel. The multiple pixel circuits 14 and the multiple light-emitting elements 30 are electrically connected to each other correspondingly. The pixel circuits 14 are configured to transmit drive currents to the light-emitting elements 30 under the action of signals from drive signal lines (such as a scanning signal line, a data signal line, and a power signal line) on the display panel, so as to drive the light-emitting elements 30 to emit light. The light-emitting elements 30 and the pixel circuits 14 electrically connected to the light-emitting elements 30 together constitute sub-pixels of the display panel. The multiple sub-pixels are arranged according to a certain pattern. The brightness of different sub-pixels is precisely controlled so that the display of a complete image can be implemented.

It is to be noted that the manner in which the multiple pixel circuits 14 and the multiple light-emitting elements 30 are arranged may be configured according to actual requirements, which is not specifically limited in the embodiment of the present disclosure.

As shown in FIG. 2, optionally, a pixel circuit 14 may include at least one first thin-film transistor T1. A first thin-film transistor T1 may include a first active layer T11, a first gate T12, and a first source/drain electrode T13 that are stacked.

Furthermore, as shown in FIG. 2, a gate insulating layer 41 is disposed between the first active layer T11 and the first gate T12, and an interlayer insulating layer 42 is disposed between the first gate T12 and the first source/drain electrode T13 so that electrical isolation is performed between the first gate T12 and the first active layer T11 and between the first gate T12 and the first source/drain electrode T13 to ensure normal operation of the first thin-film transistor T1.

The pixel circuit 14 may be a 1T1C circuit, a 2T1C circuit, a 7T1C circuit, an 8T1C circuit, or other types of pixel circuits known to those skilled in the art. A specific structure of the pixel circuit 14 may be configured according to actual requirements of the display panel and is not limited in the embodiment of the present disclosure.

Furthermore, the light-emitting element 30 may include an organic light-emitting diode (OLED), a micro light-emitting diode (such as Micro-LED or Mini-LED), or other types of light-emitting devices, which is not specifically limited in the embodiment of the present disclosure.

As shown in FIG. 2, the example in which the light-emitting element 30 is the OLED is used for description, and the light-emitting element 30 may include an anode 301, a light-emitting layer 302, and a cathode 303 that are stacked. When the pixel circuit 14 provides a drive current for the light-emitting element 30, electrons are injected into the light-emitting layer 302 through the cathode 30, and holes are injected into the light-emitting layer 302 through the anode 301. The electrons and the holes recombine in the light-emitting layer 302 to release energy, thereby causing the light-emitting layer 302 to emit visible light.

The light-emitting layer 302 is configured to be made of different materials so that visible light in different colors can be emitted. For example, the light-emitting elements 30 may include a red light-emitting element that emits red light, a blue light-emitting element that emits blue light, and a green light-emitting element that emits green light to implement the display of a color image. However, colors of the light-emitting elements 30 are not limited to these. In some embodiments, the light-emitting elements 30 may also include a white light-emitting element that emits white light. The colors of the light-emitting elements 30 are not specifically limited in the embodiment of the present disclosure.

Furthermore, as shown in FIGS. 1 and 2, multiple photosensitive elements 20 arranged in an array are disposed in the display region AA of the display panel. The photosensitive elements 20 are configured to receive optical signals and convert the optical signals into electric signals.

Optionally, as shown in FIG. 2, the photosensitive element 20 includes the first electrode 201, the semiconductor layer 202, and a second electrode 203 that are stacked.

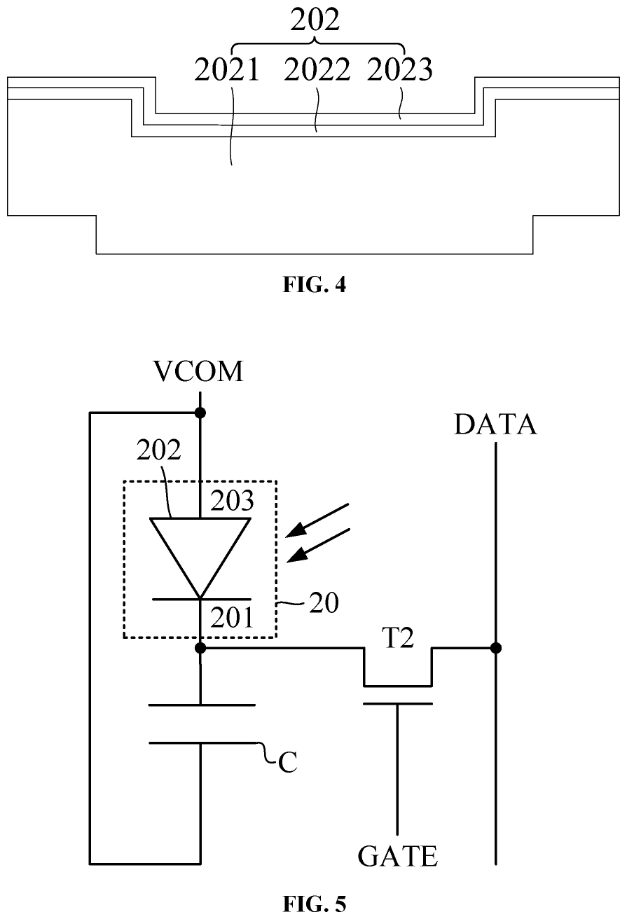

FIG. 4 is a sectional view of a semiconductor layer according to an embodiment of the present disclosure. As shown in FIG. 4, optionally, the semiconductor layer 202 adopts a PIN structure. The PIN structure is photosensitive and unidirectionally conductive. In the absence of light, the PIN structure has a very small reverse saturation leakage current, and a photodiode is cut off in this case. When exposed to light, the PIN structure has a greatly increased reverse saturation leakage current, thereby forming a photocurrent.

For example, the semiconductor layer 202 includes an N-type doped N-type semiconductor layer 2021, an undoped intrinsic semiconductor layer 2022, and a P-type doped P-type semiconductor layer 2023 that are stacked sequentially.

Optionally, the N-type semiconductor layer 2021 may be doped with pentavalent elements (such as phosphorus or arsenic) to increase the concentration of free electrons. The N-type semiconductor layer 2023 can provide a large number of free electrons. When the PIN structure is forward-biased, these electrons may be injected into the intrinsic semiconductor layer 2022 and eventually reach the P-type semiconductor layer 2023.

The intrinsic semiconductor layer 2022 is an undoped pure semiconductor material with a very low carrier concentration. The intrinsic semiconductor layer 2022 can provide a high-resistance region. Thus, the intrinsic semiconductor layer 2022 can effectively block the flow of carriers when the PIN structure is reverse-biased so that the intrinsic semiconductor layer 2022 can withstand a relatively high voltage without breakdown. When the PIN structure is forward-biased, the intrinsic semiconductor layer 2022 allows the carriers (such as the electrons and the holes) to pass.

The P-type semiconductor layer 2023 may be doped with trivalent elements (such as boron or aluminum) to increase the concentration of holes. When the PIN structure is forward-biased, the P-type semiconductor layer 2023 receives the electrons injected from the N-type semiconductor layer 2021, and the electrons recombine with the holes in the P-type semiconductor layer 2023 to form a current.

Furthermore, the P-type semiconductor layer 2023 is electrically connected to the second electrode 203, and the N-type semiconductor layer 2021 is electrically connected to the first electrode 201 so that the first electrode 201, the semiconductor layer 202, and the second electrode 203 constitute the photodiode. In this case, the second electrode 203 serves as the positive electrode of the photodiode, and the first electrode 201 serves as the negative electrode of the photodiode.

Optionally, the material of the second electrode 203 may include a transparent material such as indium tin oxide (ITO) or indium zinc oxide (IZO) to avoid the case where the second electrode 203 shields light and affects the response of the photosensitive element 20 to light.

Optionally, the photosensitive element 20 may be configured to implement a fingerprint recognition function or other biometric recognition functions.

FIG. 5 is a structural diagram of a fingerprint recognition module according to an embodiment of the present disclosure. As shown in FIGS. 2 and 5, exemplarily, the photosensitive element 20 may constitute the fingerprint recognition module together with a storage capacitor C and a second thin-film transistor T2. The storage capacitor C is connected in series between the first electrode 201 of the photodiode and the second electrode 203 of the photodiode. The second electrode 203 is electrically connected to a reference voltage signal line VCOM. The second thin-film transistor T2 is connected in series between the first electrode 201 and a signal line DATA. The gate of the second thin-film transistor T2 is electrically connected to a switch control line GATE. The semiconductor layer 202 of the photodiode is connected between the first electrode 201 and the second electrode 203.

The operation principle of the fingerprint recognition module may be as follows. During fingerprint recognition, at least light-emitting elements in a region touched by a finger emit light to be incident to the finger, reflected light from the finger is incident to the semiconductor layer 202, and the semiconductor layer 202 generates a photocurrent under the action of the reflected light. Since distances from ridges in the fingerprint of the finger to the semiconductor layer 202 are different from distances from valleys in the fingerprint of the finger to the semiconductor layer 202, the intensity of reflected light formed at ridge positions and received by the semiconductor layer 202 is different from the intensity of reflected light formed at valley positions and received by the semiconductor layer 202 and converted photocurrents have different magnitudes, and thus, valley signals and ridge signals can be distinguished through the photocurrents, thereby implementing the fingerprint recognition function.

For example, at a fingerprint recognition stage, the reference voltage signal line VCOM inputs a low-voltage signal to the second electrode 203 of the photosensitive element 20, and the signal line DATA inputs a high-voltage signal. The entire fingerprint recognition stage includes a preparation stage, a fingerprint signal acquisition stage, and a fingerprint signal detection stage. At the preparation stage, a driver chip (not shown in the figure) electrically connected to the fingerprint recognition module controls, through the switch control line GATE, the second thin-film transistor T2 to be turned on, and the storage capacitor C is charged until the storage capacitor C is fully charged, thereby forming a fixed voltage difference across the storage capacitor C. At the fingerprint recognition stage, the second thin-film transistor T2 is controlled, through the switch control line GATE, to be turned off. When the finger touches the display panel, the light emitted from the light-emitting elements 30 is incident to the finger and is reflected on a surface of the fingerprint to form the reflected light that is incident to the semiconductor layer 202. The semiconductor layer 202 receives the reflected light and generates the corresponding photocurrent according to the intensity of the received reflected light. This photocurrent affects a potential of the storage capacitor C, causing a voltage drop in the storage capacitor C. At the fingerprint signal detection stage, the second thin-film transistor T2 may be controlled, through the switch control line GATE, to be turned on, thereby reading potential information of the storage capacitor C through the signal line DATA and thus acquiring the voltage drop of the storage capacitor C. When multiple fingerprint recognition modules are arranged in an array, the fingerprint on the surface of the finger makes the surface of the finger uneven, resulting in different brightness of the reflected light. Thus, different semiconductor layers 202 generate the photocurrents with the different magnitudes, ultimately causing different voltage drops in corresponding storage capacitors C. Therefore, the valley signals and the ridge signals can be distinguished according to the voltage drops of the storage capacitors C, thereby implementing the fingerprint recognition function of the display panel.

In some embodiments, at the fingerprint signal detection stage, the second thin-film transistor T2 may be controlled, through the switch control line GATE, to be turned on. A potential difference exists between the two electrodes of the storage capacitor C, and the storage capacitor C remains in a charging state. The magnitude of the photocurrent can also be determined by detecting the quantity of charges charged into the storage capacitor C, thereby implementing the fingerprint recognition function of the display panel.

With continued reference to FIG. 2, optionally, the second thin-film transistor T2 may include a second active layer T21, a second gate T22, and a second source/drain electrode T23 that are stacked. The second thin-film transistor T2 and the first thin-film transistor T1 may be located in the same film, that is, the second thin-film transistor T2 is disposed in an array layer 40 including the pixel circuits 14. Thus, the number of films can be reduced, which is conducive to reducing the thickness of the display panel. In addition, the second thin-film transistor T2 and the first thin-film transistor T1 may be prepared in the same manufacturing process, which helps to shorten process time and reduce manufacturing costs.

The array layer 40 typically includes multiple metal wires to transmit signals, thereby driving the pixel circuits 14 to operate. As shown in FIG. 2, optionally, along the direction perpendicular to the plane where the base substrate 10 is located, the array layer 40 is located between the base substrate 10 and the light-emitting elements 30, which can prevent the light emitted by the light-emitting elements 30 from being shielded by the metal wires in the array layer 40, thereby ensuring the light emission efficiency of the display panel. In addition, the array layer 40 is located between the base substrate 10 and the photosensitive elements 20, which can prevent the photosensitive elements 20 from being shielded by the metal wires in the array layer 40, thereby ensuring the photosensitivity of the photosensitive elements 20.

It is to be noted that a specific structure of the fingerprint recognition module is not limited to the structure provided in the preceding embodiment. In other embodiments, a function, a specific structure, a circuit connection relationship, and a film configuration of the photosensitive element 20 may be configured according to the actual requirements and are not limited in the embodiment of the present disclosure.

It is to be understood that in this embodiment, the photosensitive elements 20 are disposed in the display panel, and an external optical sensor is not needed, which is conducive to reducing the overall module thickness. In addition, the photosensitive elements 20 are located in the display region AA, and the light emitted by the light-emitting elements 30 of the display panel can be used as a light source to implement fingerprint recognition and detection. Moreover, the space is saved, and the screen-to-body ratio of the display panel is increased.

Optionally, as shown in FIG. 1, along a direction parallel to the plane where the base substrate 10 is located, the photosensitive element 20 is located between adjacent light-emitting elements 30, that is, the photosensitive element 20 is disposed in the gap between the adjacent light-emitting elements 30. In this manner, the photosensitive element 20 does not affect the aperture ratio of the display panel, and the light emitted by the adjacent light-emitting elements 30 can be effectively used for implementing the fingerprint recognition function.

With continued reference to FIGS. 1 and 2, the array layer 40 typically includes multiple thin-film transistors, the multiple metal wires, and the like. These structures cause an uneven upper surface of the array layer 40. In this embodiment, as shown in FIG. 2, along the direction perpendicular to the plane where the base substrate 10 is located, the first planarization layer 11 may be disposed between the array layer 40 and the photosensitive elements 20. The first planarization layer 11 serves to planarize the surface so that a flat surface is provided for preparing the photosensitive elements 20 above the array layer 40, which is conducive to ensuring consistent performance of each photosensitive element 20.

Optionally, the material of the first planarization layer 11 includes an organic material. The organic material may form a uniform and continuous film through spin coating and has a good filling ability for uneven surfaces, thereby enabling the first planarization layer 11 to achieve a good planarization effect.

Furthermore, as shown in FIG. 2, the inventors find through research that after the photosensitive element 20 is embedded into the display panel, stacked layers, such as the first metal layer 12 including the first electrode 201 and the semiconductor layer 202, are added on the first planarization layer 11 to form structures of the photosensitive element 20. Since the semiconductor layer 202 is relatively thick, a relatively long etching time is required when the patterned semiconductor layer 202 is formed through etching. Physical bombardment for etching plasma easily damages the first metal layer 12 and the first planarization layer 11 under the semiconductor layer 202, causing over-etching damage to the first metal layer 12 and the first planarization layer 11.

Based on the preceding technical problem, in this embodiment, as shown in FIG. 2, along the direction perpendicular to the plane where the base substrate 10 is located, the etching stop layer 13 is added between the first metal layer 12 and the semiconductor layer 202. The etching stop layer 13 is configured to ensure that the etching is limited to the film where the semiconductor layer 202 is located when the patterned semiconductor layer 202 is formed through the etching, so as to protect the first metal layer 12 and the first planarization layer 11 under the etching stop layer 13. Thus, the over-etching damage to the first metal layer 12 and the first planarization layer 11 is avoided during the preparation of the semiconductor layer 202.

Optionally, the material of the etching stop layer 13 includes an inorganic material. The film formed by the inorganic material has good compactness and relatively low porosity. In the process where the patterned semiconductor layer 202 is formed through the etching, the etching process can be effectively hindered, preventing the first metal layer 12 and the first planarization layer 11 under the etching stop layer 13 from being damaged by over-etching.

Furthermore, as shown in FIGS. 2 and 3, the etching stop layer 13 includes the second opening 132 configured to correspond to the first electrode 201. Along the direction perpendicular to the plane where the base substrate 10 is located, the overlapping region exists among the second opening 132, the first electrode 201, and the semiconductor layer 202 so that the first electrode 201 and the semiconductor layer 202 can be in contact with each other through the second opening 132, thereby forming the structures of the photosensitive element 20.

The inventors find through further research that during a process procedure (a high-temperature site) involving a high temperature in a fabrication process, some substances in the first planarization layer 11 may volatilize and release a gas (an outgas). When the compact etching stop layer 13 covers a large area of the first planarization layer 11, the gas cannot escape smoothly, which may cause the etching stop layer 13 to peel off from the first planarization layer 11. Thus, the reliability of the display panel is affected.

Based on the preceding technical problem, in this embodiment, as shown in FIGS. 2 and 3, the first opening 131 is provided in the etching stop layer 13 in the display region AA. The first opening 131 is a through hole penetrating through the etching stop layer 13 and can expose the first planarization layer 11 below. Thus, the first opening 131 can serve as a gas release channel. In this manner, during the process procedure (the high-temperature site) involving the high temperature in the fabrication process, the gas generated by the first planarization layer 11 can be released outward through the first opening 131, thereby preventing the etching stop layer 13 from peeling off from the first planarization layer 11 and improving the reliability of the display panel.

Furthermore, along the direction perpendicular to the plane where the base substrate 10 is located, the first opening 131 does not overlap with the first metal layer 12. That is, the first opening 131 is provided in a region of the display region AA other than the region where the first metal layer 12 is located. The first opening 131 is provided in the gap between metal members in the first metal layer 12, and the first metal layer 12 does not exist in the region directly under the first opening 131. In this manner, in the process where the patterned semiconductor layer 202 is formed through the etching, the first metal layer 12 can be effectively protected against the damage caused by the over-etching.

In summary, in the display panel provided in the embodiment of the present disclosure, the photosensitive elements are disposed in the display panel, thereby reducing the overall module thickness, and the first planarization layer is disposed under the photosensitive elements for planarization to ensure the consistent performance of each photosensitive element. Furthermore, the etching stop layer is added between the first metal layer and the semiconductor layer so that when the patterned semiconductor layer is formed through the etching, the first metal layer and the first planarization layer are protected, and the over-etching damage to the first metal layer and the first planarization layer is avoided. In addition, the first opening that does not overlap with the first metal layer is provided in the etching stop layer, serving as the gas release channel. During the process procedure (the high-temperature site) involving the high temperature in the fabrication process, the gas generated by the first planarization layer can be released outward through the first opening, thereby preventing the etching stop layer from peeling off from the first planarization layer and improving the reliability of the display panel.

Optionally, as shown in FIG. 2, along the direction parallel to the plane where the base substrate 10 is located, the length of the first opening 131 is d1, and d1≥2.5 μm.

First openings 131 may have multiple linear dimensions in the direction parallel to the plane where the base substrate 10 is located because the first openings 131 have different shapes. The length d1 of the first opening 131 may be the minimum linear dimension of the first opening 131 in all directions, but is not limited thereto.

In this embodiment, the length d1 of the first opening 131 is set to be at least 2.5 μm so as to ensure that in the process where the first opening 131 is formed through etching, the etching stop layer 13 can be completely penetrated to form the through hole. This configuration avoids incomplete etching or a film residue caused by an excessively small dimension of the first opening 131, thereby ensuring that the gas released from the first planarization layer 11 can escape smoothly through the first opening 131 and preventing the etching stop layer from peeling off from the first planarization layer.

It is to be noted that the specific shape and dimension of the first opening 131 may be configured according to the actual requirements and are not specifically limited in the embodiment of the present disclosure.

For example, the first opening 131 may be a rectangle of 8 μm×4 μm to meet an exhaust requirement without occupying excessive layout space, but the shape and dimension of the first opening 131 are not limited thereto.

Optionally, as shown in FIGS. 2 and 3, the area of the first opening 131 is smaller than the area of the second opening 132.

The second opening 132 is configured to implement the electrical connection between the first electrode 201 and the semiconductor layer 202. The second opening 132 is configured to have a relatively large area so that the contact area between the first electrode 201 and the semiconductor layer 202 can be increased, which is conducive to reducing the contact resistance between the first electrode 201 and the semiconductor layer 202 and can avoid poor contact caused by misalignment.

The first opening 131 is only used for releasing the gas. The first opening 131 only needs to be formed as the through hole penetrating through the etching stop layer 13 to implement exhaust. In this embodiment, the single first opening 131 is configured to have a relatively small area so that the exhaust requirement is met, and the first opening 131 can be prevented from occupying excessive layout space, thereby preventing the first opening 131 from encroaching on layout space of the first metal layer 12.

In addition, the first opening 131 and the second opening 132 are typically formed in the same etching process. If the area of the first opening 131 is configured to be much larger than the area of the second opening 132, in the process where the first opening 131 and the second opening 132 are formed through the etching, it is necessary to extend etching time to completely etch and remove the etching stop layer 13 in the first opening 131 with the larger area. As a result, the second opening 132 with the smaller area continues being over-etched after the etching is completed. Ultimately, the area of the second opening 132 may exceed the design area, affecting the structural integrity of the etching stop layer 13. Thus, during subsequent preparation of the semiconductor layer 202, the etching stop layer 13 cannot achieve an expected protection effect on the first metal layer 12 under the etching stop layer 13, resulting in unexpected over-etching damage to the first metal layer 12 under the etching stop layer 13.

Furthermore, the multiple first openings 131 with relatively small areas may be distributed in the gap regions between the various metal members of the first metal layer 12, thereby improving the uniformity of the exhaust, ensuring that the gas released from the first planarization layer 11 can escape smoothly through the first openings 131, and preventing the etching stop layer 13 from peeling off from the first planarization layer 11.

Optionally, as shown in FIGS. 2 and 3, along the direction parallel to the plane where the base substrate 10 is located, the distance L2 between a boundary of the second opening 132 and a boundary of the first electrode 201 is 1 μm to 2.5 μm.

The distance L2 between the boundary of the second opening 132 and the boundary of the first electrode 201 is set to be at least 1 μm so that a sufficient photolithography alignment margin can be provided to ensure that the second opening 132 is still completely located on the first electrode 201 within a process variation range. Thus, a stable electrical connection between the semiconductor layer 202 and the first electrode 201 is ensured.

In addition, the distance L2 between the boundary of the second opening 132 and the boundary of the first electrode 201 is set to be less than or equal to 2.5 μm, which can prevent the first electrode 201 from occupying excessive space and is conducive to improving a pixel aperture ratio and a pixel integration density.

For example, the distance L2 between the boundary of the second opening 132 and the boundary of the first electrode 201 may be 1.65 μm, but is not limited thereto.

Optionally, as shown in FIGS. 2 and 3, along the direction parallel to the plane where the base substrate 10 is located, the shortest distance between the first opening 131 and a metal member located in the first metal layer 12 is d2, and d2≥1.5 μm.

The metal member in the first metal layer 12 refers to a conductive pattern in the first metal layer 12. The metal member may include the first electrode 201 and other wires and connection structures.

In this embodiment, the shortest distance d2 between the first opening 131 and the metal member located in the first metal layer 12 is the minimum horizontal distance between the edge of the first opening 131 and the edge of any metal member in the first metal layer 12. The shortest distance d2 is set to be at least 1.5 μm so that it can be ensured that the first opening 131 can still maintain, within an etching process variation range, the state of not overlapping with any metal member in the first metal layer 12. Thus, in the process where the patterned semiconductor layer 202 is formed through the etching, the first metal layer 12 is effectively protected, and the first metal layer 12 is prevented from being damaged by the over-etching at the first opening 131, thereby improving the reliability and yield of the display panel.

Optionally, as shown in FIGS. 2 and 3, the first metal layer 12 further includes a photosensitive element connection line 121, a first power signal line 122, and a data signal line 123 that extend along a first direction X and are arranged along a second direction Y. The first direction X intersects with the second direction Y. The photosensitive element connection line 121 is connected to the first electrode 201. Along the direction parallel to the plane where the base substrate 10 is located, the first opening 131 is located between the data signal line 123 and the first power signal line 122, and/or the first opening 131 is located between the photosensitive element 20 and the first power signal line 122, and/or the first opening 131 is located between the photosensitive element connection line 121 and the first power signal line 122.

As shown in FIG. 3, the first direction X may be perpendicular to the second direction Y. For example, the first direction X may be a column direction and the second direction Y may be a row direction, but the first direction X and the second direction Y are not limited thereto.

In this embodiment, as shown in FIG. 3, in addition to the first electrode 201, the first metal layer 12 may further include the photosensitive element connection line 121, the first power signal line 122, and the data signal line 123 that extend along the first direction X and are arranged along the second direction Y.

The photosensitive element connection line 121 is configured to connect the first electrode 201 to a driver circuit (for example, the storage capacitor C and/or the second thin-film transistor T2) of the photosensitive element 20.

The first power signal line 122 is configured to supply a power voltage (for example, a first power voltage PVDD) to the pixel circuit 14.

The data signal line 123 is configured to supply a data signal to the pixel circuit 14.

In this embodiment, as shown in FIGS. 2 and 3, along the direction parallel to the plane where the base substrate 10 is located, the first opening 131 may be provided in the gap region between the data signal line 123 and the first power signal line 122, the first opening 131 may be provided in the gap region between the photosensitive element 20 (for example, the first electrode 201) and the first power signal line 122, or the first opening 131 may be provided in the gap region between the photosensitive element connection line 121 and the first power signal line 122. With this configuration, without additionally increasing a layout area, the outgas is released, preventing the etching stop layer from peeling off from the first planarization layer. In addition, the isolation between the first opening 131 and the first metal layer 12 is ensured. Thus, in the process where the patterned semiconductor layer 202 is formed through the etching, the first metal layer 12 is prevented from being damaged by the over-etching at the first opening 131, thereby improving the reliability and yield of the first metal layer 12.

It is to be noted that the first openings 131 may be provided at two or more positions in the gap region between the data signal line 123 and the first power signal line 122, the gap region between the photosensitive element 20 (for example, the first electrode 201) and the first power signal line 122, and the gap region between the photosensitive element connection line 121 and the first power signal line 122. This configuration aims to release the outgas at multiple points, thereby improving the uniformity of the exhaust, ensuring that the gas released by the first planarization layer 11 can escape smoothly through the first openings 131, and preventing the etching stop layer from peeling off from the first planarization layer.

Furthermore, one first opening 131 or two or more first openings 131 may be provided in any one of the gap region between the data signal line 123 and the first power signal line 122, the gap region between the photosensitive element 20 (for example, the first electrode 201 of the photosensitive element 20) and the first power signal line 122, and the gap region between the photosensitive element connection line 121 and the first power signal line 122, which is not specifically limited in the embodiment of the present disclosure.

Optionally, as shown in FIGS. 2 and 3, the first power signal line 122 includes a first wire section 1221 and a second wire section 1222 that are connected to each other, and the first wire section 1221 and the second wire section 1222 are arranged along the first direction X. Along the second direction Y, the width d8 of the second wire section 1222 is greater than the width d7 of the first wire section 1221. Along the direction parallel to the plane where the base substrate 10 is located, the first opening 131 is located between the photosensitive element 20 and the first wire section 1221, and/or the first opening 131 is located between the first wire section 1221 and the data signal line 123, and/or the first opening 131 is located between the photosensitive element connection line 121 and the second wire section 1222, and/or the first opening 131 is located between the data signal line 123 and the second wire section 1222.

Specifically, as shown in FIG. 3, the first power signal line 122 is formed by the first wire section 1221 and the second wire section 1222.

Along the second direction Y, the width d8 of the second wire section 1222 is relatively large so that the second wire section 1222 can shield light and prevent ambient light from entering a region (such as a channel region of the thin-film transistor in the pixel circuit 14) that should not be exposed to light. The second wire section 1222 protects components (such as the thin-film transistor in the pixel circuit 14) under the first power signal line 122 from being affected by unexpected light and avoids the generation of an unnecessary photocurrent that affects the performance of the pixel circuit 14 and consequently affects the display effect of the display panel.

In addition, the width d7 of the first wire section 1221 is set to be relatively small so that a sufficient wiring gap can be formed between the first wire section 1221 and another metal member (such as the data signal line 123, the photosensitive element connection line 121, and the first electrodes 201) in the first metal layer 12, thereby improving the space utilization of the display region AA.

Furthermore, along the direction parallel to the plane where the base substrate 10 is located, the first opening 131 may be provided in the gap region between the photosensitive element 20 (for example, the first electrode 201 of the photosensitive element 20) and the first wire section 1221, the first opening 131 may be provided in the gap region between the first wire section 1221 and the data signal line 123, the first opening 131 may be provided in the gap region between the photosensitive element connection line 121 and the second wire section 1222, or the first opening 131 may be provided in the gap region between the data signal line 123 and the second wire section 1222. The positions of the first openings 131 are carefully planned so that necessary exhaust channels can be provided without additionally increasing the layout area, thereby preventing the etching stop layer 13 from peeling off from the first planarization layer 11. In addition, the isolation between the first opening 131 and the first metal layer 12 is ensured. Thus, in the process where the patterned semiconductor layer 202 is formed through the etching, the first metal layer 12 is prevented from being damaged by the over-etching at the first opening 131, thereby improving the reliability and yield of the first metal layer 12.

It is to be noted that the first openings 131 may be provided at two or more positions in the gap region between the photosensitive element 20 (for example, the first electrode 201 of the photosensitive element 20) and the first wire section 1221, the gap region between the first wire section 1221 and the data signal line 123, the gap region between the photosensitive element connection line 121 and the second wire section 1222, and the gap region between the data signal line 123 and the second wire section 1222. This configuration aims to release the outgas at multiple points, thereby improving the uniformity of the exhaust, ensuring that the gas released by the first planarization layer 11 can escape smoothly through the first openings 131, and preventing the etching stop layer 13 from peeling off from the first planarization layer 11.

Furthermore, one first opening 131 or two or more first openings 131 may be provided in any one of the gap region between the photosensitive element 20 (for example, the first electrode 201 of the photosensitive element 20) and the first wire section 1221, the gap region between the first wire section 1221 and the data signal line 123, the gap region between the photosensitive element connection line 121 and the second wire section 1222, and the gap region between the data signal line 123 and the second wire section 1222, which is not specifically limited in the embodiment of the present disclosure.

Optionally, as shown in FIGS. 2 and 3, along the direction parallel to the plane where the base substrate 10 is located, the first opening 131 located between the photosensitive element 20 and the first wire section 1221 is a first-type opening 131A, the first opening 131 located between the first wire section 1221 and the data signal line 123 is a second-type opening 131B, the first opening 131 located between the photosensitive element connection line 121 and the second wire section 1222 is a third-type opening 131C, and the first opening 131 located between the data signal line 123 and the second wire section 1222 is a fourth-type opening 131D. The area of the third-type opening 131C is larger than the area of the first-type opening 131A and larger than the area of the second-type opening 131B. The area of the fourth-type opening 131D is larger than the area of the first-type opening 131A and larger than the area of the second-type opening 131B.

Specifically, as shown in FIGS. 2 and 3, the first-type opening 131A is located in the gap region between the photosensitive element 20 and the first wire section 1221. The first-type opening 131A is adjacent to the photosensitive element 20, and layout space near the photosensitive element 20 is relatively restricted. In this gap region, the etching stop layer 13 covers a relatively small area of the first planarization layer 11, resulting in relatively low outgas release pressure. The single first-type opening 131A is configured to have the relatively small area so that the exhaust requirement is met, the first-type opening 131A can be prevented from occupying excessive layout space, and it is ensured that the first-type opening 131A can still maintain, within the etching process variation range, the state of not overlapping with the first electrode 201 of the photosensitive element 20 and the first wire section 1221. Thus, in the process where the patterned semiconductor layer 202 is formed through the etching, the first electrode 201 and the first wire section 1221 are prevented from being damaged by the over-etching at the first-type opening 131A, thereby improving the reliability and yield.

The second-type opening 131B is located in the gap region between the first wire section 1221 and the data signal line 123. Signal lines are relatively dense in this region. In this gap region, the etching stop layer 13 covers a relatively small area of the first planarization layer 11, resulting in relatively low outgas release pressure. The single second-type opening 131B is configured to have the relatively small area so that the exhaust requirement is met, the second-type opening 131B can be prevented from occupying excessive layout space, and it is ensured that the second-type opening 131B can still maintain, within the etching process variation range, the state of not overlapping with the first wire section 1221 and the data signal line 123. Thus, in the process where the patterned semiconductor layer 202 is formed through the etching, the first wire section 1221 and the data signal line 123 are prevented from being damaged by the over-etching at the second-type opening 131B, thereby improving the reliability and yield.

The third-type opening 131C is located in the gap region between the photosensitive element connection line 121 and the second wire section 1222. This region has relatively sufficient space. In this gap region, the etching stop layer 13 covers a relatively large area of the first planarization layer 11, resulting in relatively high outgas release pressure. The single third-type opening 131C is configured to have the relatively large area, which is conducive to the outgas release. Thus, the etching stop layer 13 is prevented from peeling off from the first planarization layer 11. In addition, the third-type opening 131C with the relatively large dimension is easier to precisely manufacture in the etching process. Thus, the dimensional stability of the third-type opening 131C and the exhaust reliability of the third-type opening 131C can be improved.

The fourth-type opening 131D is located in the gap region between the data signal line 123 and the second wire section 1222. This region has relatively sufficient space. In this gap region, the etching stop layer 13 covers a relatively large area of the first planarization layer 11, resulting in relatively high outgas release pressure. The single fourth-type opening 131D is configured to have the relatively large area, which is conducive to the outgas release. Thus, the etching stop layer 13 is prevented from peeling off from the first planarization layer 11. In addition, the fourth-type opening 131D with the relatively large dimension is easier to precisely manufacture in the etching process. Thus, the dimensional stability of the fourth-type opening 131D and the exhaust reliability of the fourth-type opening 131D can be improved.

In this embodiment, the areas of the first openings 131 at different positions are designed differently so that the exhaust requirements and space constraints of different regions can be matched. Thus, on the premise of ensuring the film quality of the first metal layer 12, efficient and uniform outgas release is implemented, and the etching stop layer 13 is prevented from peeling off from the first planarization layer 11.

Optionally, as shown in FIGS. 2 and 3, the etching stop layer 13 includes the multiple first openings 131. Along the direction parallel to the plane where the base substrate 10 is located, the shortest distance between two adjacent first openings 131 is d3, and d3≥1.5 μm.

The multiple first openings 131 are provided in the etching stop layer 13 to release the outgas of the first planarization layer 11 under the etching stop layer 13 in a high-temperature process, which can improve the uniformity of the outgas release and is conducive to preventing the etching stop layer 13 from peeling off from the first planarization layer 11.

Furthermore, if the shortest distance d3 between the two adjacent first openings 131 is excessively small, it is easy to cause the communication between the two adjacent first openings 131 when the first openings 131 are formed through the etching, affecting the structural integrity of the etching stop layer 13. As a result, during the subsequent preparation of the semiconductor layer 202, the etching stop layer 13 cannot achieve an expected protection effect on the first planarization layer 11 under the etching stop layer 13, resulting in unexpected over-etching damage to the first planarization layer 11 under the etching stop layer 13.

Based on the preceding technical problem, in this embodiment, the shortest distance d3 between the two adjacent first openings 131 is set to be greater than or equal to 1.5 μm. Thus, the case can be avoided where the two adjacent first openings 131 communicate with each other, causing the area of a single first opening 131 to exceed a design area, which ensures the structural integrity of the etching stop layer 13 and is conducive to reducing the over-etching damage to the first planarization layer 11 during the preparation of the semiconductor layer 202.

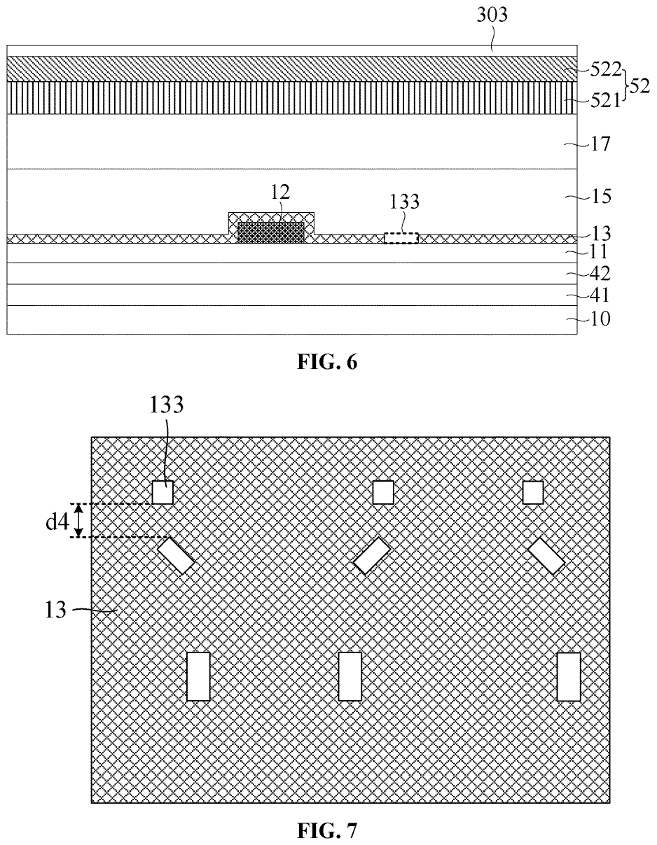

FIG. 6 is a sectional view of part of a display panel in a non-display region according to an embodiment of the present disclosure, and FIG. 7 is a partial structural diagram of an etching stop layer in a non-display region according to an embodiment of the present disclosure. As shown in FIGS. 1, 6, and 7, optionally, the display panel further includes a non-display region NA located on at least one side of the display region AA. In the non-display region NA, the etching stop layer 13 includes at least one third opening 133, and the at least one third opening 133 is located in a region other than the region where the first metal layer 12 is located.

The display region AA is a main region in the display panel for displaying images. The display region AA includes core display components such as the light-emitting elements 30 and the pixel circuits 14. The non-display region NA is a peripheral region surrounding the display region AA and used for disposing a scan driving circuit, a signal line, a power line, and a bonding region.

In this embodiment, the non-display region NA is also provided with the first planarization layer 11, the first metal layer 12, and the etching stop layer 13. During the process procedure (the high-temperature site) involving the high temperature in the fabrication process, the first planarization layer 11 in the non-display region NA also releases an outgas. When the compact etching stop layer 13 covers a large area of the first planarization layer 11 in the non-display region NA, the gas cannot escape smoothly, which may cause the etching stop layer 13 to peel off from the first planarization layer 11 in the non-display region NA. Thus, the reliability of the display panel is affected.

Based on the preceding technical problem, in this embodiment, as shown in FIGS. 6 and 7, a third opening 133 is provided in the etching stop layer 13 in the non-display region NA. The third opening 133 is a through hole penetrating through the etching stop layer 13 and can expose the first planarization layer 11 below the etching stop layer 13. Thus, the third opening 133 can serve as a gas release channel. In this manner, during the process procedure (the high-temperature site) involving the high temperature in the fabrication process, the gas generated by the first planarization layer 11 in the non-display region NA can be released outward through the third opening 133, thereby preventing the etching stop layer 13 in the non-display region NA from peeling off from the first planarization layer 11 and improving the reliability of the display panel.

Furthermore, along the direction perpendicular to the plane where the base substrate 10 is located, the third opening 133 does not overlap with the first metal layer 12. That is, the third opening 133 is provided in a region of the non-display region NA other than the region where the first metal layer 12 is located. The third opening 133 is provided in the gap between metal members in the first metal layer 12, and the first metal layer 12 does not exist in the region directly under the third opening 133. In this manner, in the process where the patterned semiconductor layer 202 is formed through the etching, the first metal layer 12 can be effectively protected against the damage caused by the over-etching.

Optionally, as shown in FIGS. 2, 3, 6, and 7, the area of the first opening 131 is S1, and the area of the third opening 133 is S3, where 0.8≤S3/S1≤1.2.

In addition, the first opening 131 and the third opening 133 are typically formed in the same etching process. If the area difference between the single first opening 131 and the single third opening 133 is relatively large, in the process where the first opening 131 and the third opening 133 are formed through the etching, it is necessary to extend etching time to completely etch and remove the etching stop layer 13 in the opening with the larger area. As a result, the opening with the smaller area continues being over-etched after the etching is completed. Ultimately, the area of the relatively small opening may exceed the design area thereof, affecting the structural integrity of the etching stop layer 13. Thus, during the subsequent preparation of the semiconductor layer 202, the etching stop layer 13 cannot achieve the expected protection effect on the first metal layer 11 under the etching stop layer 13, resulting in the unexpected over-etching damage to the first metal layer 11 under the etching stop layer 13.

Based on the preceding technical problem, in this embodiment, the area S1 of the first opening 131 and the area S3 of the third opening 133 are set to satisfy 0.8≤S3/S1≤1.2 so that the area of the first opening 131 in the display region AA and the area of the third opening 133 in the non-display region NA tend to be consistent. In this manner, when the first opening 131 and the third opening 133 are formed through the etching, the etching variation between the display region AA and the non-display region NA can be reduced so that the dimension of the first opening 131 and the dimension of the third opening 133 can be controlled within design ranges, which helps to improve the reliability of the display panel.

For example, the area S1 of the first opening 131 is set to be equal to the area S3 of the third opening 133 so that when the first opening 131 and the third opening 133 are formed through the etching, the etching time of the first opening 131 and the etching time of the third opening 133 are more consistent, further reducing the etching variation between the display region AA and the non-display region NA. Thus, the dimension of the first opening 131 and the dimension of the third opening 133 are consistent, which helps to further improve the reliability of the display panel.

Optionally, as shown in FIGS. 2, 3, 6, and 7, the etching stop layer 13 includes the multiple first openings 131 and the multiple third openings 133. Along the direction parallel to the plane where the base substrate 10 is located, the shortest distance between the two adjacent first openings 131 is d3, and the shortest distance between two adjacent third openings 133 is d4, where 0.8≤d4/d3≤1.2.

The multiple first openings 131 are provided in the etching stop layer 13 in the display region AA to release the outgas of the first planarization layer 11 under the etching stop layer 13 in the high-temperature process, which can improve the uniformity of the outgas release in the display region AA and is conducive to preventing the etching stop layer 13 in the display region AA from peeling off from the first planarization layer 11.

Similarly, the multiple third openings 133 are provided in the etching stop layer 13 in the non-display region NA to release the outgas of the first planarization layer 11 under the etching stop layer 13 in the high-temperature process, which can improve the uniformity of the outgas release in the non-display region NA and is conducive to preventing the etching stop layer 13 in the non-display region NA from peeling off from the first planarization layer 11.

Furthermore, the first openings 131 and the third openings 133 are typically formed in the same etching process. If the arrangement density of the first openings 131 in the display region AA and the arrangement density of the third openings 133 in the non-display region NA are significantly different, in the process where the first openings 131 and the third openings 133 are formed through the etching, it is necessary to extend etching time to completely etch and remove the etching stop layer 13 in the openings with a relatively high density. As a result, the openings with a relatively low density continue being over-etched after the etching is completed. Ultimately, the areas of the openings with the relatively low density may exceed the design areas thereof, affecting the structural integrity of the etching stop layer 13. Thus, during the subsequent preparation of the semiconductor layer 202, the etching stop layer 13 cannot achieve the expected protection effect on the first metal layer 11 under the etching stop layer 13, resulting in the unexpected over-etching damage to the first metal layer 11 under the etching stop layer 13.

Based on the preceding technical problem, in this embodiment, the shortest distance d3 between the two adjacent first openings 131 and the shortest distance d4 between the two adjacent third openings 133 are set to satisfy 0.8≤d4/d3≤1.2 so that the spacing between the first openings 131 in the display region AA and the spacing between the third openings 133 in the non-display region NA tend to be consistent. This can cause the distribution density of the first openings 131 in the display region AA and the distribution density of the third openings 133 in the non-display region NA to tend to be consistent. Thus, when the first openings 131 and the third openings 133 are formed through the etching, the etching variation between the display region AA and the non-display region NA can be reduced so that the dimensions of the first openings 131 and the dimensions of the third openings 133 can be controlled within design ranges, which helps to improve the reliability of the display panel.

For example, the shortest distance d3 between the two adjacent first openings 131 is set to be equal to the shortest distance d4 between the two adjacent third openings 133 so that when the first openings 131 and the third openings 133 are formed through the etching, the etching time of the first openings 131 and the etching time of the third openings 133 are more consistent, further reducing the etching variation between the display region AA and the non-display region NA. Thus, the dimensions of the first openings 131 and the dimensions of the third openings 133 are closer to design values, which helps to further improve the reliability of the display panel.

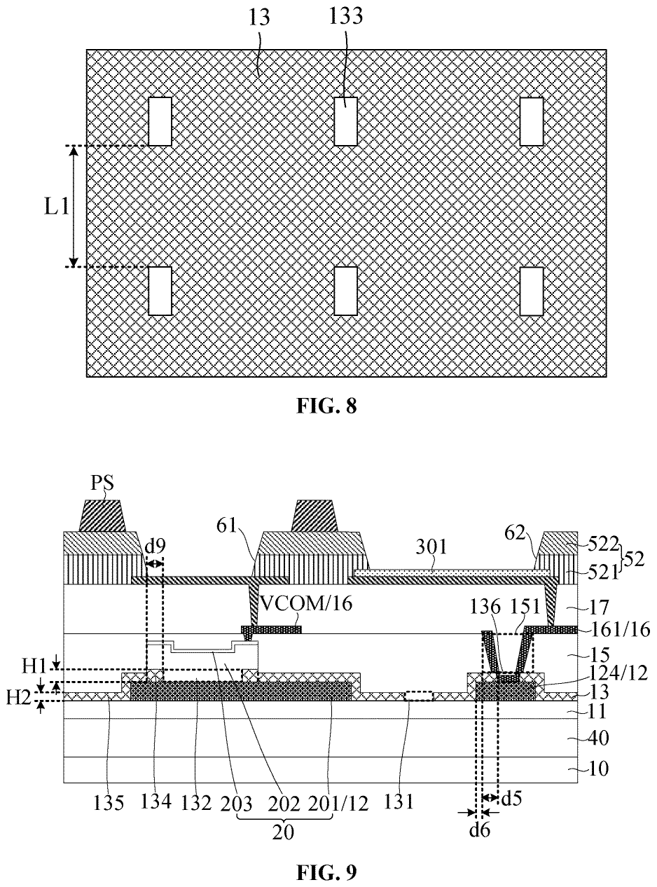

FIG. 8 is another partial structural diagram of an etching stop layer in a non-display region according to an embodiment of the present disclosure. As shown in FIG. 8, optionally, the etching stop layer 13 includes the multiple third openings 133, and the multiple third openings 133 are arranged in an array. Along the direction parallel to the plane where the base substrate 10 is located, the distance between the two adjacent third openings 133 is L1, where 15 μm≤L1≤25 μm.

The multiple third openings 133 arranged in the array are provided in the etching stop layer 13 in the non-display region NA to release the outgas of the first planarization layer 11 under the etching stop layer 13 in the high-temperature process, which can improve the uniformity of the outgas release in the non-display region NA and is conducive to preventing the etching stop layer 13 in the non-display region NA from peeling off from the first planarization layer 11.

Furthermore, the distance L1 between the two adjacent third openings 133 is set to satisfy 15 μm≤L1≤25 μm so that the third openings 133 in the non-display region NA can be matched with the first openings 131 in the display region AA. This causes the distribution density of the third openings 133 in the non-display region NA and the distribution density of the first openings 131 in the display region AA to tend to be more consistent. Thus, when the first openings 131 and the third openings 133 are formed through the etching, the etching variation between the display region AA and the non-display region NA can be reduced so that the dimensions of the first openings 131 and the dimensions of the third openings 133 can be controlled within the design ranges, which helps to improve the reliability of the display panel.

It is to be noted that the specific shape and dimension of the third opening 133 may be configured according to the actual requirements and are not specifically limited in the embodiment of the present disclosure.

Optionally, the shape of the third opening 133 may be the same as the shape of the first opening 131, thereby helping to reduce the etching variation between the display region AA and the non-display region NA when the first opening 131 and the third opening 133 are formed through the etching. Thus, the shape and dimension of the first opening 131 and the shape and dimension of the third opening 133 can be controlled within the design ranges, thereby improving the reliability of the display panel.

For example, the third opening 133 may be a rectangle of 8 μm×4 μm and the distance L1 between the two adjacent third openings 133 may be 19 μm so that the third opening 133 is matched with the first opening 131 in the display region AA. In this case, the ratio of the area of all openings in the etching stop layer 13 (for example, the sum of the areas of the first opening 131, the second opening 132, and the third opening 133) and the area of the display panel (for example, the sum of the areas of the display region AA and the non-display region NA) is greater than or equal to 8.5%, which can implement efficient outgas release and effectively prevent the etching stop layer 13 from peeling off from the first planarization layer 11, which it is not limited thereto.

FIG. 9 is a sectional view of part of a display panel in a display region according to an embodiment of the present disclosure. As shown in FIG. 9, optionally, the etching stop layer 13 includes a first etching stop section 134 and a second etching stop section 135. Along the direction perpendicular to the plane where the base substrate 10 is located, the first etching stop section 134 is configured to overlap with the semiconductor layer 202. The second etching stop section 135 is located in a region other than the region where the semiconductor layer 202 is located. The thickness H1 of the first etching stop section 134 is greater than the thickness H2 of the second etching stop section 135.

Specifically, as shown in FIG. 9, the first etching stop section 134 is part of the etching stop layer 13 in the region where the semiconductor layer 202 is located, and the second etching stop section 135 is part of the etching stop layer 13 in the region other than the region where the semiconductor layer 202 is located.

In this embodiment, the first etching stop section 134 is configured to have the relatively large thickness H1, which is conducive to protecting the first metal layer 12 under the semiconductor layer 202 and prevents the first metal layer 12 at the semiconductor layer 202 from being damaged by the over-etching. Thus, the resistance of the photosensitive element 20 to process damage can be improved, thereby improving the reliability and yield of the photosensitive element 20.

In addition, the second etching stop section 135 has the relatively small thickness H2, which can reduce the coverage thickness of the second etching stop section 135 over the first planarization layer 11 in the region other than the region where the semiconductor layer 202 is located. Thus, the release of the outgas from the first planarization layer 11 can be promoted, and the accumulation of interface stress between the first planarization layer 11 and the second etching stop section 135 can be reduced, thereby preventing the etching stop layer 13 from peeling off from the first planarization layer 11.

Optionally, as shown in FIG. 9, the thickness of the first etching stop section 134 is H1, and the thickness of the second etching stop section 135 is H2, where ½≤H2/H1≤⅔.

The thickness H2 of the second etching stop section 135 is set to be ½ to ⅔ of the thickness H1 of the first etching stop section 134 so that it is ensured that the second etching stop section 135 can protect the first planarization layer 11 and the first metal layer 12 covered by the second etching stop section 135 and prevent the first planarization layer 11 and the first metal layer 12 under the second etching stop section 135 from being damaged by the over-etching, and the second etching stop section 135 is prevented from being excessively thick and affecting the release of the outgas of the first planarization layer 11. This configuration also helps to reduce the accumulation of the interface stress between the first planarization layer 11 and the second etching stop section 135, preventing the etching stop layer 13 from peeling off from the first planarization layer 11.

The specific thicknesses of the first etching stop section 134 and the second etching stop section 135 may be set according to the actual requirements. For example, the thickness H1 of the first etching stop section 134 is 300 μm, and the thickness H2 of the second etching stop section 135 is 100 μm to 200 μm, but the thickness H1 of the first etching stop section 134 and the thickness H2 of the second etching stop section 135 are not limited thereto.

Optionally, as shown in FIG. 9, along the direction parallel to the plane where the base substrate 10 is located, the distance d9 between the boundary of the second opening 132 and a boundary of the semiconductor layer 202 is greater than or equal to 1.8 μm.

The distance d9 between the boundary of the second opening 132 and the boundary of the semiconductor layer 202 is set to be at least 1.8 μm so that a sufficient photolithography alignment margin can be provided to ensure that the semiconductor layer 202 still completely covers the second opening 132 within a process variation range. Thus, the stable electrical connection between the semiconductor layer 202 and the first electrode 201 is ensured.

For example, the distance d9 between the boundary of the second opening 132 and the boundary of the semiconductor layer 202 may be 1.8 μm, but is not limited thereto.

Optionally, as shown in FIGS. 2 and 9, the display panel provided in the embodiment of the present disclosure further includes a second planarization layer 15 and a second metal layer 16. The second planarization layer 15 is located on one side of the semiconductor layer 202 facing away from the base substrate 10. The second metal layer 16 is located on one side of the second planarization layer 15 facing away from the base substrate 10. The etching stop layer 13 further includes a fourth opening 136, and the second planarization layer 15 includes a fifth opening 151. The first metal layer 12 further includes a pixel circuit connection portion 124 electrically connected to the pixel circuit 14, and the second metal layer 16 includes a light-emitting element connection portion 161 electrically connected to the light-emitting element 30. Along the direction perpendicular to the plane where the base substrate 10 is located, an overlapping region exists among the pixel circuit connection portion 124, the fourth opening 136, the fifth opening 151, and the light-emitting element connection portion 161, and the pixel circuit connection portion 124 and the light-emitting element connection portion 161 are connected to each other through the fourth opening 136 and the fifth opening 151. Along the direction perpendicular to the plane where the base substrate 10 is located, the fifth opening 151 covers the fourth opening 136.

Specifically, since the semiconductor layer 202 has a relatively large thickness, a relatively large step is formed on the first planarization layer 11. This step affects the flatness of a film above the step. For example, the flatness of the anode 301 is affected, causing the light-emitting layer 302 on the anode 301 to be uneven. As a result, when the display panel is viewed from different directions at the same tilt angle, the brightness of the light-emitting layer 302 varies, which causes an inconsistent color cast at the same tilt viewing angle in different directions. That is, the inconsistent color cast in four directions is caused, affecting the display effect of the display panel.

Based on the preceding technical problem, in this embodiment, as shown in FIGS. 2 and 9, along the direction perpendicular to the plane where the base substrate 10 is located, the second planarization layer 15 is disposed between the semiconductor layer 202 and the light-emitting elements 30. The second planarization layer 15 is configured to planarize the surface and can provide a relatively flat surface for the preparation of the light-emitting elements 30, thereby ensuring that films located on the second planarization layer 15 can be uniformly deposited and avoiding the color cast problem caused by an uneven surface.

Furthermore, to completely cover the relatively large step, a relatively thick planarization layer is required. However, if only one relatively thick second planarization layer 15 is disposed, the material of the second planarization layer 15 may not flow uniformly during the preparation of the second planarization layer 15, leading to local thickness differences and affecting the planarization effect.

Based on the preceding technical problem, in this embodiment, as shown in FIGS. 2 and 9, a third planarization layer 17 may be disposed on the second planarization layer 15. The planarization effect is achieved by the second planarization layer 15 and the third planarization layer 17 together. In addition, the second planarization layer 15 and the third planarization layer 17 are prepared layer by layer so that the step can be gradually reduced and a flatter surface can be formed finally, thereby achieving a better planarization effect.

Furthermore, as shown in FIGS. 2 and 9, the second metal layer 16 including the light-emitting element connection portion 161 is disposed between the second planarization layer 15 and the third planarization layer 17. The first metal layer 12 further includes the pixel circuit connection portion 124. The light-emitting element connection portion 161 is connected to the pixel circuit connection portion 124 through the fifth opening 151 in the second planarization layer 15 and the fourth opening 136 in the etching stop layer 13. In this case, the anode 301 of the light-emitting element 30 is connected to the pixel circuit 14 through the light-emitting element connection portion 161 and the pixel circuit connection portion 124 in sequence, thereby implementing the electrical connection between the light-emitting element 30 and the pixel circuit 14. This structure can decompose the traditional deep punching connection manner into the manner of connecting multiple shallow holes, which avoids problems such as non-uniform etching and poor contact caused by a single through hole required to penetrate through multiple films and is conducive to improving manufacturing yield and reliability.

Furthermore, a vertical projection of the fifth opening 151 on the base substrate 10 covers a vertical projection of the fourth opening 136 on the base substrate 10, which can compensate for a process alignment error and ensure the reliability of the electrical connection between the pixel circuit connection portion 124 and the light-emitting element connection portion 161.

Optionally, as shown in FIGS. 2 and 9, the reference voltage signal line VCOM is located in the second metal layer 16. That is, the reference voltage signal line VCOM and the light-emitting element connection portion 161 are located in the same film. Thus, the number of films can be reduced, which is conducive to reducing the thickness of the display panel. In addition, the reference voltage signal line VCOM and the light-emitting element connection portion 161 may be prepared in the same manufacturing process. Thus, process time can be shortened, and manufacturing costs can be reduced. As shown in FIG. 2, the reference voltage signal line VCOM is electrically connected to the cathode 303. That is, in this embodiment, the second electrode 203 of the photosensitive element 20 receives a cathode potential. Of course, the reference voltage signal line VCOM may not be electrically connected to the cathode 303. In this case, the reference voltage signal line VCOM may be connected to a separate signal. For example, the reference voltage signal line VCOM may be extended into the non-display region of the display panel in a plan view to be connected to a required signal from a reference voltage signal bus in the non-display region. The manner in which the reference voltage signal line VCOM is connected to the signal and a potential connected to the reference voltage signal line VCOM may be configured to be set according to the needs of those skilled in the art and are not specifically limited here.

Optionally, as shown in FIG. 9, along the direction parallel to the plane where the base substrate 10 is located, the shortest distance between a boundary of the fifth opening 151 and a boundary of the fourth opening 136 is d5, and d5≥1 μm.

Specifically, as shown in FIG. 9, the area of the fifth opening 151 is larger than the area of the fourth opening 136, and the fifth opening 151 covers the region where the fourth opening 136 is located. The shortest distance d5 between the boundary of the fifth opening 151 and the boundary of the fourth opening 136 is set to be at least 1 μm, so as to ensure that the fifth opening 151 can still completely cover the fourth opening 136 in the case of lithography-etching overlay error. Thus, the reliability of the electrical connection between the pixel circuit connection portion 124 and the light-emitting element connection portion 161 is ensured.

Optionally, as shown in FIG. 9, along the direction perpendicular to the plane where the base substrate 10 is located, the pixel circuit connection portion 124 covers the fifth opening 151. Along the direction parallel to the plane where the base substrate 10 is located, the shortest distance between the boundary of the fifth opening 151 and a boundary of the pixel circuit connection portion 124 is d6, where d6≥1.6 μm.

Specifically, as shown in FIG. 9, the fifth opening 151 is provided in the region where the pixel circuit connection portion 124 is located so that the fifth opening 151 only exposes the pixel circuit connection portion 124 and does not expose other structures such as the first planarization layer 11. Thus, the first planarization layer 11 can be protected during the preparation of the semiconductor layer 202.

In addition, the shortest distance d6 between the boundary of the fifth opening 151 and the boundary of the pixel circuit connection portion 124 is set to be at least 1.6 μm so that it can be ensured that in the case of an etching offset error, the pixel circuit connection portion 124 can still be located in the region where the pixel circuit connection portion 124 is located. Thus, the first planarization layer 11 is protected, and it is ensured that the light-emitting element connection portion 161 can form a reliable electrical connection to the pixel circuit connection portion 124 through the fifth opening 151, thereby effectively preventing poor contact caused by the offset of the fifth opening 151.

Optionally, as shown in FIG. 3, at least two first openings 131 have different areas.

The multiple first openings 131 are provided in the etching stop layer 13 to release the outgas of the first planarization layer 11 under the etching stop layer 13 in the high-temperature process, which can improve the uniformity of the outgas release and is conducive to preventing the etching stop layer 13 from peeling off from the first planarization layer 11.

Furthermore, the at least two first openings 131 are configured to have the different areas so that the areas of the first openings 131 at the different positions can be matched with the exhaust requirements and space constraints of the different positions. Thus, the film quality is ensured, the efficient and uniform outgas release is implemented, and the etching stop layer 13 is prevented from peeling off from the first planarization layer 11.

Optionally, as shown in FIG. 3, the first metal layer 12 further includes the first power signal line 122 and the data signal line 123 that extend along the first direction X and are arranged along the second direction Y. The first direction X intersects with the second direction Y. At least two first openings 131 that are arranged along the first direction X have different areas, and/or at least two first openings 131 that are arranged along the second direction Y have the same area.

For the specific structures and functions of the first power signal line 122 and the data signal line 123, reference may be made to the preceding embodiments. The details are not repeated here.

In this embodiment, as shown in FIG. 3, the at least two first openings 131 that are arranged along the first direction X are configured to have the different areas so that the areas of first openings 131 at different positions in the first direction X can be matched with the exhaust requirements and space constraints of different gap positions between the first power signal line 122 and the data signal line 123. Thus, the film quality is ensured, the efficient and uniform outgas release is implemented, and the etching stop layer 13 is prevented from peeling off from the first planarization layer 11.

In some embodiments, the at least two first openings 131 that are arranged along the second direction Y may be configured to have the same area so that it can be ensured that the areas of first openings 131 near different first power signal lines 122 and different data signal lines 123 tend to be consistent. This configuration is conducive to ensuring the loss consistency of signals transmitted by the different first power signal lines 122 and the different data signal lines 123.

Optionally, as shown in FIGS. 2, 6, and 9, the display panel provided in the embodiment of the present disclosure further includes a pixel defining layer 52, and the pixel defining layer 52 is located on one side of the third planarization layer 17 facing away from the base substrate 10. The pixel defining layer 52 includes a sixth opening 61, and along the direction perpendicular to the plane where the base substrate 10 is located, the sixth opening 61 and the photosensitive element 20 at least partially overlap.

Specifically, as shown in FIGS. 2, 6, and 9, the pixel defining layer 52 is disposed on the third planarization layer 17. The pixel defining layer 52 is disposed on the anode 301. A seventh opening 62 is provided in the pixel defining layer 52. The light-emitting layer 302 may be formed in the seventh opening 62 of the pixel defining layer 52.

The pixel defining layer 52 is configured to define a boundary of each pixel. The pixel defining layer 52 isolates the light-emitting elements 30 from each other so that current leakage and optical crosstalk between adjacent pixels can be effectively prevented, thereby improving the display quality.

With continued reference to FIGS. 2, 6, and 9, optionally, the pixel defining layer 52 may include a first pixel defining layer 521 and a second pixel defining layer 522 that are stacked, and the second pixel defining layer 522 is located on one side of the first pixel defining layer 521 facing away from the base substrate 10. The first pixel defining layer 521 may be configured to be a black pixel defining layer to absorb light between adjacent pixels and prevent optical crosstalk between the adjacent pixels.

In this embodiment, as shown in FIGS. 2, 6, and 9, the sixth opening 61 is provided in the pixel defining layer 52, and along the direction perpendicular to the plane where the base substrate 10 is located, the sixth opening 61 and the photosensitive element 20 at least partially overlap, reducing shielding of light by the pixel defining layer 52. Thus, more light can pass through the pixel defining layer 52 to be incident to the photosensitive element 20 so that the performance of the photosensitive element 20 can meet an application requirement (for example, the improvement of fingerprint recognition efficiency).

With continued reference to FIGS. 2 and 9, optionally, the cathode 303 is located in the first opening 61. The cathode 303 may be electrically connected to the reference voltage signal line VCOM, Thus, the low-voltage signal is provided to the second electrode 203 of the photosensitive element 20 through the first opening 61 by using the cathode 303. This configuration eliminates the need for additional wiring or complex circuit connections, can simplify the structure of the display panel, and helps to simplify a fabrication flow and reduce production costs.

In other embodiments, a connection line may be directly disposed in the film where the reference voltage signal line VCOM is located so that the low-voltage signal is connected, thereby simplifying the fabrication flow and reducing the production costs, which is not specifically limited in the embodiment of the present disclosure.

With continued reference to FIG. 9, optionally, the display panel further includes spacers PS, and the spacers PS are located on one side of the pixel defining layer 52 facing away from the base substrate 10. A spacer PS is located on the pixel defining layer 52 between adjacent pixels and may be configured to support structures such as a mask, an encapsulation layer, or a cover plate, thereby preventing devices in the display panel from being deformed or damaged due to external forces or pressure.

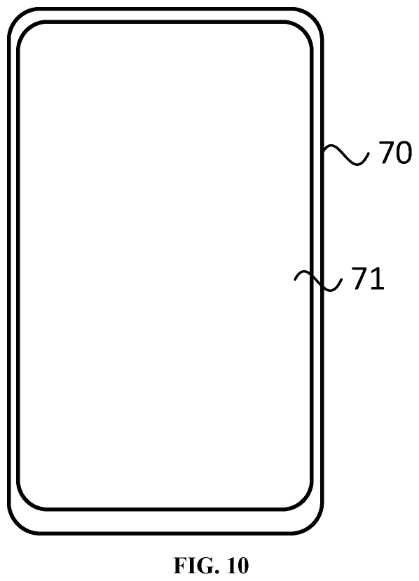

Based on the same inventive concept, the embodiment of the present disclosure further provides a display device. FIG. 10 is a structural diagram of the display device according to the embodiment of the present disclosure. As shown in FIG. 10, the display device 70 includes the display panel 71 described in any embodiment of the present disclosure. Therefore, the display device 70 provided in the embodiment of the present disclosure has the technical effects of the technical solution of any one of the preceding embodiments, and structures that are the same as or correspond to the structures in the preceding embodiments and the explanation of the terms are not repeated herein.

The display device 70 provided in the embodiment of the present disclosure may be the cellphone shown in FIG. 10 or may be any other electronic product having a display function. The electronic product includes, but is not limited to, a television, a laptop, a desktop display, a tablet, a digital camera, a smart bracelet, smart glasses, an in-vehicle display, a medical device, an industrial control device, or an interactive touch terminal. The type of the display device 70 is not specially limited in the embodiment of the present disclosure.

Based on the same inventive concept, the embodiment of the present disclosure further provides a preparation method for a display panel for preparing any display panel provided in the preceding embodiments. Structures that are the same as or correspond to the structures in the preceding embodiments and the explanation of the terms are not repeated herein.

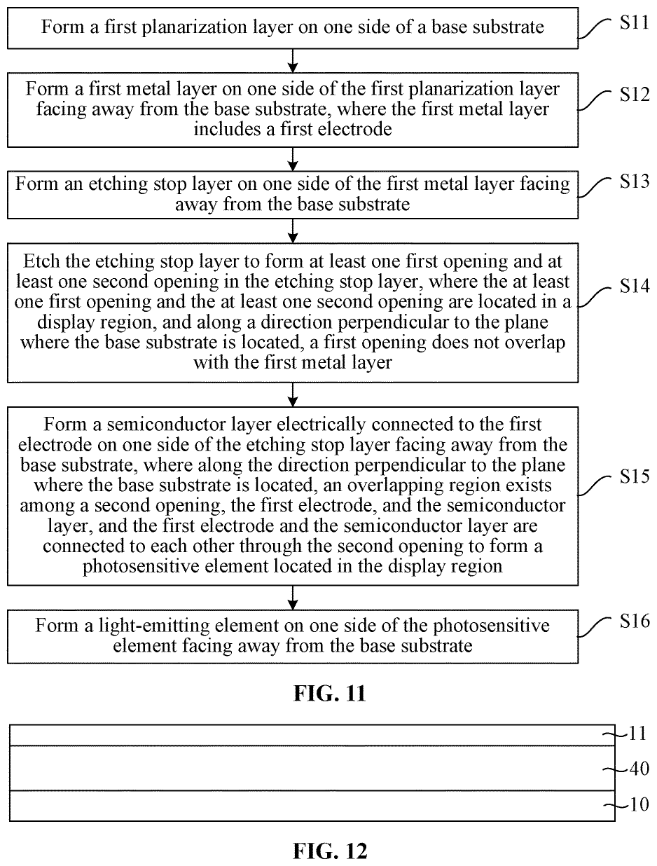

FIG. 11 is a flowchart of the preparation method for a display panel according to the embodiment of the present disclosure, and FIGS. 12 to 21 are structural diagrams illustrating a manufacturing method for a display panel according to the embodiment of the present disclosure. As shown in FIGS. 11 to 21, the preparation method provided in the embodiment of the present disclosure includes the steps described below.

In S11, a first planarization layer is formed on one side of a base substrate.

Specifically, as shown in FIG. 12, the base substrate 10 is used for bearing various components in the display panel. An array layer 40 may be disposed on the base substrate 10, and pixel circuits (not shown in the figure) are disposed in the array layer 40 to drive light-emitting elements to emit light.

The entire first planarization layer 11 is prepared on the array layer 40 to serve a planarization function.

Optionally, the material of the first planarization layer 11 includes an organic material so that the first planarization layer 11 can achieve a good planarization effect.

In S12, a first metal layer is formed on one side of the first planarization layer facing away from the base substrate, where the first metal layer includes a first electrode.

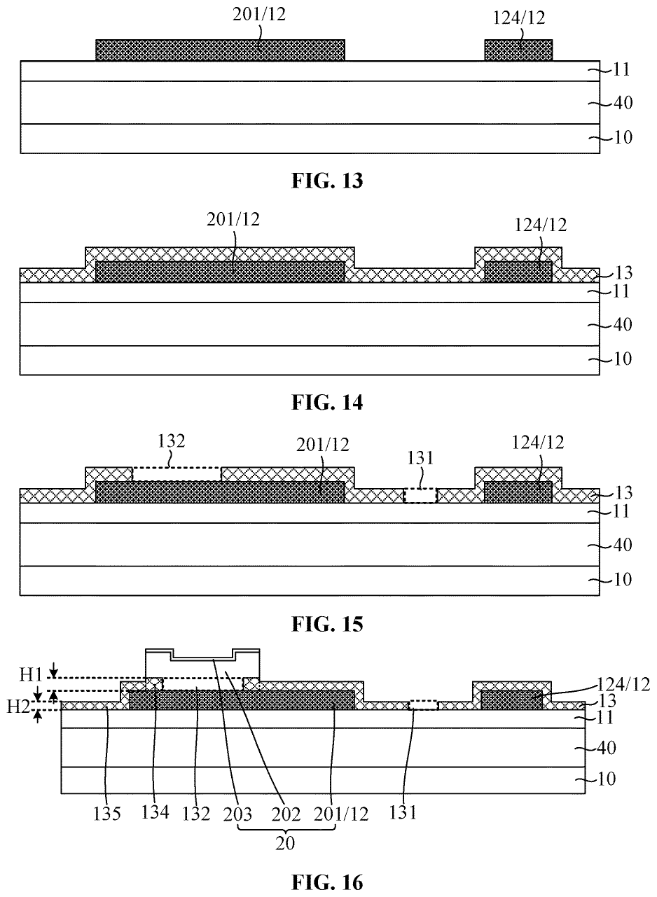

Specifically, as shown in FIG. 13, an entire first metal material layer (not shown in the figure) is prepared on the first planarization layer 11, and the first metal material layer is etched to form the first metal layer 12 including the first electrode 201.

Optionally, in the process where the first metal material layer is etched, a pixel circuit connection portion 124 may be formed simultaneously. In this case, both the pixel circuit connection portion 124 and the first electrode 201 are located in the first metal layer 12, which can reduce the number of films, is conducive to reducing the thickness of the display panel, and can shorten process time and reduce manufacturing costs.

In S13, an etching stop layer is formed on one side of the first metal layer facing away from the base substrate.

Specifically, as shown in FIG. 14, the entire etching stop layer 13 is deposited on the first metal layer 12. The etching stop layer 13 is configured to protect the first metal layer 12 and the first planarization layer 11 under the etching stop layer 13 during subsequent preparation of a semiconductor layer, thereby avoiding over-etching damage to the first metal layer 12 and the first planarization layer 11 during the preparation of the semiconductor layer.

In S14, the etching stop layer is etched so that at least one first opening and at least one second opening are formed in the etching stop layer, where the at least one first opening and the at least one second opening are located in a display region, and along a direction perpendicular to the plane where the base substrate is located, a first opening does not overlap with the first metal layer.

Specifically, as shown in FIG. 15, the etching stop layer 13 is etched to form, in the etching stop layer 13, the at least one first opening 131 and the at least one second opening 132 located in the display region. A first opening 131 is a through hole penetrating through the etching stop layer 13, which can expose the first planarization layer 11 below and serve as a gas release channel. In this manner, during a process procedure (a high-temperature site) involving a high temperature in a fabrication process, a gas generated by the first planarization layer 11 can be released outward through the first opening 131, thereby preventing the etching stop layer 13 from peeling off from the first planarization layer 11 and improving the reliability of the display panel.

Along the direction perpendicular to the plane where the base substrate 10 is located, the first opening 131 does not overlap with the first metal layer 12. That is, the first opening 131 is provided in a region of the display region AA other than the region where the first metal layer 12 is located. The first opening 131 is provided in the gap between metal members in the first metal layer 12, and the first metal layer 12 does not exist in the region directly under the first opening 131. Thus, the first metal layer 12 can be effectively protected against the damage caused by over-etching.

Furthermore, a second opening 132 is also a through hole penetrating through the etching stop layer 13. Along the direction perpendicular to the plane where the base substrate 10 is located, the second opening 132 at least partially overlaps with the first electrode 201 so that the second opening 132 exposes the first electrode 201 below.

In S15, the semiconductor layer electrically connected to the first electrode is formed on one side of the etching stop layer facing away from the base substrate, where along the direction perpendicular to the plane where the base substrate is located, an overlapping region exists among the second opening, the first electrode, and the semiconductor layer, and the first electrode and the semiconductor layer are connected to each other through the second opening to form a photosensitive element located in the display region.

Specifically, as shown in FIG. 16, an entire semiconductor material layer (not shown in the figure) and an entire second electrode material layer (not shown in the figure) may be prepared on the etching stop layer 13. The semiconductor material layer and the second electrode material layer are etched to form the semiconductor layer 202 and the second electrode 203.

Along the direction perpendicular to the plane where the base substrate 10 is located, the overlapping region exists among the second opening 132, the first electrode 201, and the semiconductor layer 202 so that the first electrode 201 and the semiconductor layer 202 can be in contact with each other through the second opening 132, thereby forming structures of the photosensitive element 20.

Optionally, as shown in FIG. 16, part of the etching stop layer 13 in the region where the semiconductor layer 202 is located is a first etching stop section 134, and part of the etching stop layer 13 in the region other than the region where the semiconductor layer 202 is located is a second etching stop section 135. In the process where the semiconductor material layer is etched to form the semiconductor layer 202, the part (that is, the second etching stop section 135) of the etching stop layer 13 that is not covered by the semiconductor layer 202 can be thinned by the over-etching so that the thickness H1 of the first etching stop section 134 is greater than the thickness H2 of the second etching stop section 135. Thus, the first etching stop section 134 has the relatively large thickness H1, which is conducive to protecting the first metal layer 12 under the semiconductor layer 202 and prevents the first metal layer 12 from being damaged by the over-etching at the semiconductor layer 202. Thus, the resistance of the photosensitive element 20 to process damage can be improved, thereby improving the reliability and yield of the photosensitive element 20.

In addition, the second etching stop section 135 has the relatively small thickness H2, which can reduce the coverage thickness of the second etching stop section 135 over the first planarization layer 11 in the region other than the region where the semiconductor layer 202 is located. Thus, the release of the outgas from the first planarization layer 11 can be promoted, and the accumulation of interface stress between the first planarization layer 11 and the second etching stop section 135 can be reduced, thereby preventing the etching stop layer 13 from peeling off from the first planarization layer 11.

Optionally, the thickness H2 of the second etching stop section 135 is ½ to ⅔ of the thickness H1 of the first etching stop section 134 so that it is ensured that the second etching stop section 135 can protect the first planarization layer 11 and the first metal layer 12 covered by the second etching stop section 135 and prevent the first planarization layer 11 and the first metal layer 12 under the second etching stop section 135 from being damaged by the over-etching, and the second etching stop section 135 is prevented from being excessively thick and affecting the release of the outgas of the first planarization layer 11. This configuration also helps to reduce the accumulation of the interface stress between the first planarization layer 11 and the second etching stop section 135, preventing the etching stop layer 13 from peeling off from the first planarization layer 11.

The specific thicknesses of the first etching stop section 134 and the second etching stop section 135 may be set according to the actual requirements. For example, the thickness H1 of the semiconductor material layer is 300 μm. In the process where the semiconductor material layer is etched to form the semiconductor layer 202, the part (that is, the second etching stop section 135) of the etching stop layer 13 that is not covered by the semiconductor layer 202 is thinned by 100 μm to 200 μm, thereby forming the first etching stop section 134 with a thickness H1 of 300 μm and the second etching stop section 135 with a thickness H2 of 100 μm to 200 μm, but the thicknesses of the first etching stop section 134 and the second etching stop section 135 are not limited thereto.

In S16, a light-emitting element is formed on one side of the photosensitive element facing away from the base substrate.

Specifically, as shown in FIG. 21, the multiple light-emitting elements 30 arranged in an array are formed above photosensitive elements 20. The pixel circuits (not shown in the figure) in the array layer 40 and the light-emitting elements 30 are electrically connected to each other correspondingly. The pixel circuits are configured to transmit drive currents to the light-emitting elements 30 under the action of signals from drive signal lines (such as a scanning signal line, a data signal line, and a power signal line) on the display panel, so as to drive the light-emitting elements 30 to emit light. The light-emitting elements 30 and the pixel circuits electrically connected to the light-emitting elements 30 together constitute sub-pixels of the display panel. The multiple sub-pixels are arranged according to a certain pattern. The brightness of different sub-pixels is precisely controlled so that the display of a complete image can be implemented.

Optionally, after the semiconductor layer electrically connected to the first electrode is formed, the preparation method further includes the steps described below.

A second planarization layer is formed on one side of the semiconductor layer facing away from the base substrate.

The second planarization layer is etched to form a fifth opening in the second planarization layer.

The etching stop layer is etched to form a fourth opening in the etching stop layer.

A second metal layer is formed on one side of the second planarization layer facing away from the base substrate.

The second metal layer includes a light-emitting element connection portion electrically connected to the light-emitting element, and the first metal layer further includes the pixel circuit connection portion electrically connected to a pixel circuit.

Along the direction perpendicular to the plane where the base substrate is located, an overlapping region exists among the pixel circuit connection portion, the fourth opening, the fifth opening, and the light-emitting element connection portion, and the pixel circuit connection portion and the light-emitting element connection portion are connected to each other through the fourth opening and the fifth opening. Along the direction perpendicular to the plane where the base substrate is located, the fifth opening covers the fourth opening.

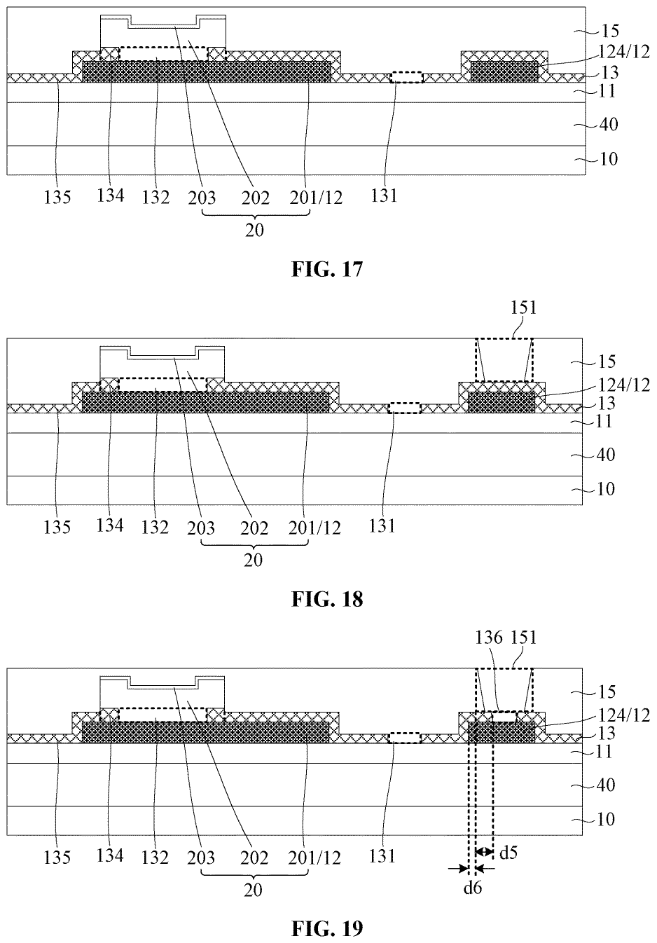

Specifically, as shown in FIG. 17, after the semiconductor layer 202 is formed, the entire second planarization layer 15 is prepared on the semiconductor layer 202 to serve a planarization function.

As shown in FIG. 18, the second planarization layer 15 is etched to form the fifth opening 151 in the second planarization layer 15. The fifth opening 151 is a through hole penetrating through the second planarization layer 15.

As shown in FIG. 19, the etching stop layer 13 exposed by the fifth opening 151 is etched to form the fourth opening 136 in the etching stop layer 13.

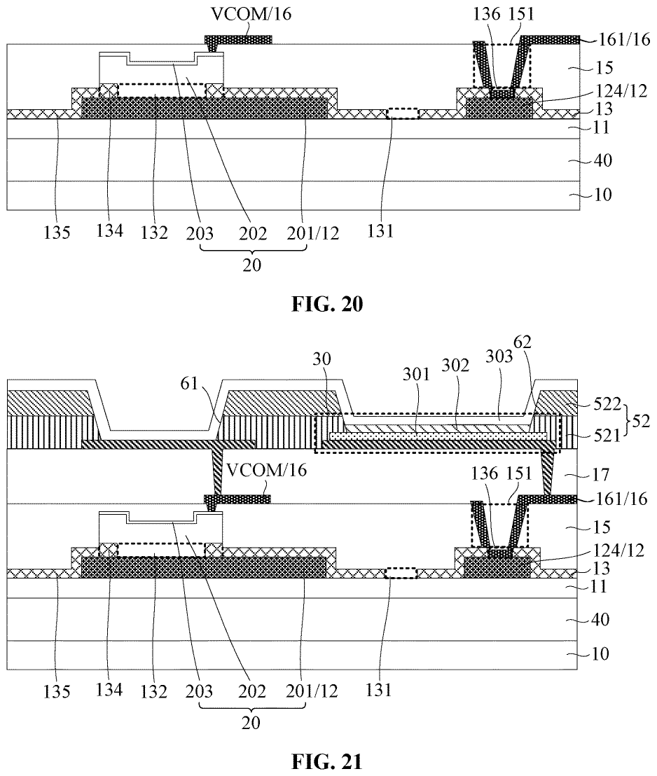

As shown in FIG. 20, the second metal layer 16 including the light-emitting element connection portion 161 is formed on the second planarization layer 15.

The first metal layer 12 further includes the pixel circuit connection portion 124. The light-emitting element connection portion 161 is connected to the pixel circuit connection portion 124 through the fifth opening 151 in the second planarization layer 15 and the fourth opening 136 in the etching stop layer 13. In this case, the anode 301 of the light-emitting element 30 is connected to the pixel circuit through the light-emitting element connection portion 161 and the pixel circuit connection portion 124 in sequence, thereby implementing the electrical connection between the light-emitting element 30 and the pixel circuit. This structure can decompose the traditional deep punching connection manner into the manner of connecting multiple shallow holes, which avoids problems such as non-uniform etching and poor contact caused by a single through hole required to penetrate through multiple films and is conducive to improving manufacturing yield and reliability.

Furthermore, a vertical projection of the fifth opening 151 on the base substrate 10 covers a vertical projection of the fourth opening 136 on the base substrate 10, which can compensate for a process alignment error and ensure the reliability of the electrical connection between the pixel circuit connection portion 124 and the light-emitting element connection portion 161.

Optionally, as shown in FIG. 20, when the second metal layer 16 is prepared, the light-emitting element connection portion 161 and the reference voltage signal line VCOM are formed simultaneously, that is, both the reference voltage signal line VCOM and the light-emitting element connection portion 161 are located in the second metal layer 16. Thus, the number of films can be reduced, which is conducive to reducing the thickness of the display panel. In addition, the reference voltage signal line VCOM and the light-emitting element connection portion 161 are prepared in the same manufacturing process so that process time can be shortened, and manufacturing costs can be reduced.

It is to be noted that if the fourth opening 136 is formed simultaneously in the process where the etching stop layer 13 is etched to form the first opening 131 and the second opening 132, the pixel circuit connection portion 124 exposed by the fourth opening 136 is easily damaged by the over-etching during the subsequent preparation of the semiconductor layer 202.

In this embodiment, in the process where the etching stop layer 13 is etched to form the first opening 131 and the second opening 132, the etching stop layer 13 on the pixel circuit connection portion 124 is not etched, that is, the fourth opening 136 is not formed, and the etching stop layer 13 is etched to form the fourth opening 136 after the semiconductor layer 202 is formed. Thus, during the preparation of the semiconductor layer 202, the etching stop layer 13 can protect the pixel circuit connection portion 124 and prevent the pixel circuit connection portion 124 from being damaged by the over-etching during the preparation of the semiconductor layer 202.

Optionally, as shown in FIG. 19, along a direction parallel to the plane where the base substrate 10 is located, the shortest distance between a boundary of the fifth opening 151 and a boundary of the fourth opening 136 is d5, and d5≥1 μm.

Specifically, as shown in FIG. 19, the area of the fifth opening 151 is larger than the area of the fourth opening 136, and the fifth opening 151 covers the region where the fourth opening 136 is located. The shortest distance d5 between the boundary of the fifth opening 151 and the boundary of the fourth opening 136 is set to be at least 1 μm, so as to ensure that the fifth opening 151 can still completely cover the fourth opening 136 in the case of lithography-etching overlay error. Thus, the reliability of the electrical connection between the pixel circuit connection portion 124 and the light-emitting element connection portion 161 is ensured.

Optionally, as shown in FIG. 19, along the direction perpendicular to the plane where the base substrate 10 is located, the pixel circuit connection portion 124 covers the fifth opening 151. Along the direction parallel to the plane where the base substrate 10 is located, the shortest distance between the boundary of the fifth opening 151 and a boundary of the pixel circuit connection portion 124 is d6, and d6≥1.6 μm.

Specifically, as shown in FIG. 19, the fifth opening 151 is provided in the region where the pixel circuit connection portion 124 is located so that the fifth opening 151 only exposes the pixel circuit connection portion 124 and does not expose other structures such as the first planarization layer 11. Thus, the first planarization layer 11 can be protected during the preparation of the semiconductor layer 202.

In addition, the shortest distance d6 between the boundary of the fifth opening 151 and the boundary of the pixel circuit connection portion 124 is set to be at least 1.6 μm so that it can be ensured that in the case of an etching offset error, the pixel circuit connection portion 124 can still be located in the region where the pixel circuit connection portion 124 is located. Thus, the first planarization layer 11 is protected, and it is ensured that the light-emitting element connection portion 161 can form a reliable electrical connection to the pixel circuit connection portion 124 through the fifth opening 151, thereby effectively preventing poor contact caused by the offset of the fifth opening 151.

It is to be noted that for the other specific structures of the display panel, reference may be made to any of the preceding embodiments. The details are not repeated here.

It is to be understood that various forms of flows shown above may be adopted with steps reordered, added, or deleted. For example, the steps described in the present disclosure may be performed in parallel, sequentially, or in different sequences, as long as the desired results of the technical solutions of the present disclosure can be achieved, and no limitation is imposed herein.

The preceding embodiments do not limit the scope of the present disclosure. It is to be understood by those skilled in the art that various modifications, combinations, sub-combinations, and substitutions may be made according to design requirements and other factors. Any modification, equivalent substitution, improvement, or the like that is made within the spirit and principle of the present disclosure is within the scope of the present disclosure.

What is claimed is:

1. A display panel, comprising:
a base substrate;
a first planarization layer located on one side of the base substrate;
a first metal layer located on one side of the first planarization layer facing away from the base substrate;
a photosensitive element located in a display region of the display panel;
an etching stop layer located on one side of the first metal layer facing away from the base substrate; and
a light-emitting element located on one side of the photosensitive element facing away from the base substrate;
wherein the photosensitive element comprises a first electrode and a semiconductor layer, the first electrode is located in the first metal layer, and the semiconductor layer is located on one side of the etching stop layer facing away from the first metal layer;
in the display region, the etching stop layer comprises at least one first opening and at least one second opening; along a direction perpendicular to a plane where the base substrate is located, a first opening of the at least one first opening does not overlap with the first metal layer, an overlapping region exists among a second opening of the at least one second opening, the first electrode, and the semiconductor layer; and the first electrode and the semiconductor layer are connected to each other through the second opening.

2. The display panel according to claim 1, wherein
along a direction parallel to the plane where the base substrate is located, a length of the first opening is d1, and d1≥2.5 μm.

3. The display panel according to claim 1, wherein
an area of the first opening is smaller than an area of the second opening.

4. The display panel according to claim 1, wherein
along a direction parallel to the plane where the base substrate is located, a shortest distance between the first opening and a metal member located in the first metal layer is d2, and d2≥1.5 μm.

5. The display panel according to claim 1, wherein
the first metal layer further comprises a photosensitive element connection line, a first power signal line, and a data signal line; wherein the photosensitive element connection line, the first power signal line, and the data signal line extend along a first direction and are arranged along a second direction;
the first direction intersects with the second direction;
the photosensitive element connection line is connected to the first electrode; and
along a direction parallel to the plane where the base substrate is located, the first opening is located between the data signal line and the first power signal line, and/or the first opening is located between the photosensitive element and the first power signal line, and/or the first opening is located between the photosensitive element connection line and the first power signal line.

6. The display panel according to claim 5, wherein
the first power signal line comprises a first wire section and a second wire section that are connected to each other, and the first wire section and the second wire section are arranged along the first direction;
along the second direction, a width of the second wire section is greater than a width of the first wire section; and
along the direction parallel to the plane where the base substrate is located, the first opening is located between the photosensitive element and the first wire section, and/or the first opening is located between the first wire section and the data signal line, and/or the first opening is located between the photosensitive element connection line and the second wire section, and/or the first opening is located between the data signal line and the second wire section.

7. The display panel according to claim 6, wherein
along the direction parallel to the plane where the base substrate is located, the first opening located between the photosensitive element and the first wire section is a first-type opening, the first opening located between the first wire section and the data signal line is a second-type opening, the first opening located between the photosensitive element connection line and the second wire section is a third-type opening, and the first opening located between the data signal line and the second wire section is a fourth-type opening;
an area of the third-type opening is larger than an area of the first-type opening and larger than an area of the second-type opening; and
an area of the fourth-type opening is larger than the area of the first-type opening and larger than the area of the second-type opening.

8. The display panel according to claim 1, wherein
the etching stop layer comprises a plurality of first openings; and
along a direction parallel to the plane where the base substrate is located, a shortest distance between two adjacent first openings of the plurality of first openings is d3, wherein d3≥1.5 μm.

9. The display panel according to claim 1, further comprising:
a non-display region located on at least one side of the display region;
wherein in the non-display region, the etching stop layer comprises at least one third opening, and the at least one third opening is located in a region other than a region where the first metal layer is located.

10. The display panel according to claim 9, wherein
an area of the first opening is S1, an area of a third opening of the at least one third opening is S3, and 0.8≤S3/S1≤1.2.

11. The display panel according to claim 9, wherein
the etching stop layer comprises a plurality of first openings and a plurality of third openings; and
along a direction parallel to the plane where the base substrate is located, a shortest distance between two adjacent first openings of the plurality of first openings is d3, a shortest distance between two adjacent third openings of the plurality of third openings is d4, and 0.8≤d4/d3≤1.2.

12. The display panel according to claim 9, wherein
the etching stop layer comprises a plurality of third openings, and the plurality of third openings are arranged in an array; and
along a direction parallel to the plane where the base substrate is located, a distance between two adjacent third openings of the plurality of third openings is L1, and 15 μm ≤L1 ≤25 μm.

13. The display panel according to claim 1, wherein
the etching stop layer comprises a first etching stop section and a second etching stop section;
along the direction perpendicular to the plane where the base substrate is located, the first etching stop section is configured to overlap with the semiconductor layer;
the second etching stop section is located in a region other than a region where the semiconductor layer is located; and
a thickness of the first etching stop section is greater than a thickness of the second etching stop section.

14. The display panel according to claim 13, wherein
the thickness of the first etching stop section is H1, the thickness of the second etching stop section is H2, and½≤H2/H1≤⅔.

15. The display panel according to claim 1, further comprising:
a second planarization layer and a second metal layer;
wherein the second planarization layer is located on one side of the semiconductor layer facing away from the base substrate;
the second metal layer is located on one side of the second planarization layer facing away from the base substrate;
the etching stop layer further comprises a fourth opening, and the second planarization layer comprises a fifth opening;
the first metal layer further comprises a pixel circuit connection portion electrically connected to a pixel circuit, and the second metal layer comprises a light-emitting element connection portion electrically connected to the light-emitting element;
along the direction perpendicular to the plane where the base substrate is located, an overlapping region exists among the pixel circuit connection portion, the fourth opening, the fifth opening, and the light-emitting element connection portion;
the pixel circuit connection portion and the light-emitting element connection portion are connected to each other through the fourth opening and the fifth opening; and
along the direction perpendicular to the plane where the base substrate is located, the fifth opening covers the fourth opening.

16. The display panel according to claim 15, wherein
along a direction parallel to the plane where the base substrate is located, a shortest distance between a boundary of the fifth opening and a boundary of the fourth opening is d5, wherein d5≥1 μm.

17. The display panel according to claim 15, wherein
along the direction perpendicular to the plane where the base substrate is located, the pixel circuit connection portion covers the fifth opening; and
along a direction parallel to the plane where the base substrate is located, a shortest distance between a boundary of the fifth opening and a boundary of the pixel circuit connection portion is d6, wherein d6≥1.6 μm.

18. The display panel according to claim 1, wherein
at least two first openings have different areas.

19. The display panel according to claim 18, wherein
the first metal layer further comprises a first power signal line and a data signal line, the first power signal line and the data signal line extend along a first direction and are arranged along a second direction;
the first direction intersects with the second direction;
at least two first openings of the at least one first opening that are arranged along the first direction have different areas; and/or at least two first openings of the at least one first opening that are arranged along the second direction have the same area.

20. A display device, comprising a display panel, wherein the display panel comprises:
a base substrate;
a first planarization layer located on one side of the base substrate;
a first metal layer located on one side of the first planarization layer facing away from the base substrate;
a photosensitive element located in a display region of the display panel;
an etching stop layer located on one side of the first metal layer facing away from the base substrate; and
a light-emitting element located on one side of the photosensitive element facing away from the base substrate;
wherein the photosensitive element comprises a first electrode and a semiconductor layer, the first electrode is located in the first metal layer, and the semiconductor layer is located on one side of the etching stop layer facing away from the first metal layer;
in the display region, the etching stop layer comprises at least one first opening and at least one second opening; along a direction perpendicular to a plane where the base substrate is located, a first opening of the at least one first opening does not overlap with the first metal layer, an overlapping region exists among a second opening of the at least one second opening, the first electrode, and the semiconductor layer; and the first electrode and the semiconductor layer are connected to each other through the second opening.
